(19) United States
(12) Patent Application Publication
(10) Pub. No.: US 2024/0388056 A1
(43) Pub. Date: Nov. 21, 2024

(54) SEMICONDUCTOR LIGHT EMITTING DEVICE

(71) Applicant: ROHM CO., LTD., Kyoto-shi (JP)

(72) Inventor: Okimoto KONDO, Kyoto-shi (JP)

(21) Appl. No.: 18/662,503

(22) Filed: May 13, 2024

(30) Foreign Application Priority Data
May 19, 2023 (JP) 2023-082725

(51) Int. Cl. H01S 5/02257; H01S 5/02208; H01S 5/0239; H01S 5/042; H01S 5/183

(52) U.S. Cl. CPC H01S 5/02257; H01S 5/02208; H01S 5/0239; H01S 5/04256; H01S 5/183

(57) ABSTRACT

A semiconductor light emitting device includes a surface emitting laser chip, a light receiving chip, a sealing member, and a reflecting portion. The surface emitting laser chip has a light emitting surface and emits laser light from the light emitting surface. The sealing member is formed of a material through which the laser light can pass and seals the surface emitting laser chip and the light receiving chip. The reflecting portion is provided in the sealing member and reflects a part of the laser light toward the light receiving chip. The light receiving chip is arranged at a position where the light receiving chip receives at least a part of reflected light by the reflecting portion.

### CROSS-REFERENCE TO RELATED APPLICATIONS

This application is based upon and claims the benefit of priority from prior Japanese Patent Application No. 2023-082725, filed on May 19, 2023, the entire contents of which are incorporated herein by reference.

### BACKGROUND

### 1. Field

The present disclosure relates to a semiconductor light emitting device.

### 2. Description of Related Art

Conventionally, as a light source device mounted on various electronic devices, a semiconductor light emitting device including a light emitting diode (LED) as a light source is known (for example, see Japanese Laid-Open Patent Publication No. 2013-41866).

### BRIEF DESCRIPTION OF THE DRAWINGS

FIG. 1 is a schematic perspective view of a semiconductor light emitting device according to a first embodiment.

FIG. 2 is a schematic plan view of the semiconductor light emitting device shown in FIG. 1 in a state in which a sealing member is removed.

FIG. 3 is a schematic cross-sectional view of the semiconductor light emitting device taken along line F3-F3 in FIG. 2.

FIG. 4 is a schematic plan view of the semiconductor light emitting device shown in FIG. 1.

FIG. 5 is a schematic cross-sectional view of a semiconductor light emitting device according to a second embodiment.

FIG. 6 is a schematic cross-sectional view in which a frame indicated by a long-dash short-dash line in FIG. 5 is enlarged.

FIG. 7 is a schematic plan view of a semiconductor light emitting device according to a third embodiment in a state in which a sealing member is removed from the semiconductor light emitting device.

FIG. 8 is a schematic cross-sectional view of the semiconductor light emitting device taken along line F8-F8 in FIG. 7.

FIG. 9 is a schematic cross-sectional view of a semiconductor light emitting device according to a fourth embodiment.

FIG. 10 is a schematic cross-sectional view of a semiconductor light emitting device according to a fifth embodiment.

FIG. 11 is a schematic cross-sectional view of a semiconductor light emitting device according to a sixth embodiment.

FIG. 12 is a schematic plan view of a surface emitting laser chip shown in FIG. 11.

FIG. 13 is a schematic plan view of a surface emitting laser chip in a semiconductor light emitting device according to a seventh embodiment.

FIG. 14 is a schematic plan view of the semiconductor light emitting device including the surface emitting laser chip of FIG. 13.

FIG. 15 is a schematic plan view of a surface emitting laser chip in a semiconductor light emitting device according to an eighth embodiment.

FIG. 16 is a schematic plan view of the semiconductor light emitting device including the surface emitting laser chip shown in FIG. 15.

FIG. 17 is an enlarged schematic cross-sectional view of a reflecting portion and its periphery in a semiconductor light emitting device of a modification.

FIG. 18 is a schematic cross-sectional view of a semiconductor light emitting device of a modification.

FIG. 19 is a schematic cross-sectional view of a semiconductor light emitting device of a modification.

FIG. 20 is a schematic cross-sectional view of a semiconductor light emitting device of a modification.

FIG. 21 is a schematic plan view of a surface emitting laser chip in a semiconductor light emitting device of a modification.

FIG. 22 is an enlarged schematic cross-sectional view of a reflecting portion and its periphery in a semiconductor light emitting device of a modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, except for operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Semiconductor light emitting devices according to embodiments of the present disclosure will now be described with reference to the attached drawings. For simplicity and clarity of illustration, components shown in the drawings are not necessarily drawn to scale. Also, to facilitate understanding, hatching lines may be omitted in cross-sectional views. The accompanying drawings are merely illustrative of embodiments of the disclosure and should not be considered as limiting the disclosure.

The detailed description below includes devices, systems, and methods that are exemplary embodiments of the present disclosure. This detailed description is merely intended for explanatory purposes, and does not intend to limit the embodiments of the present disclosure, nor the application or usage of such embodiments.

### First Embodiment

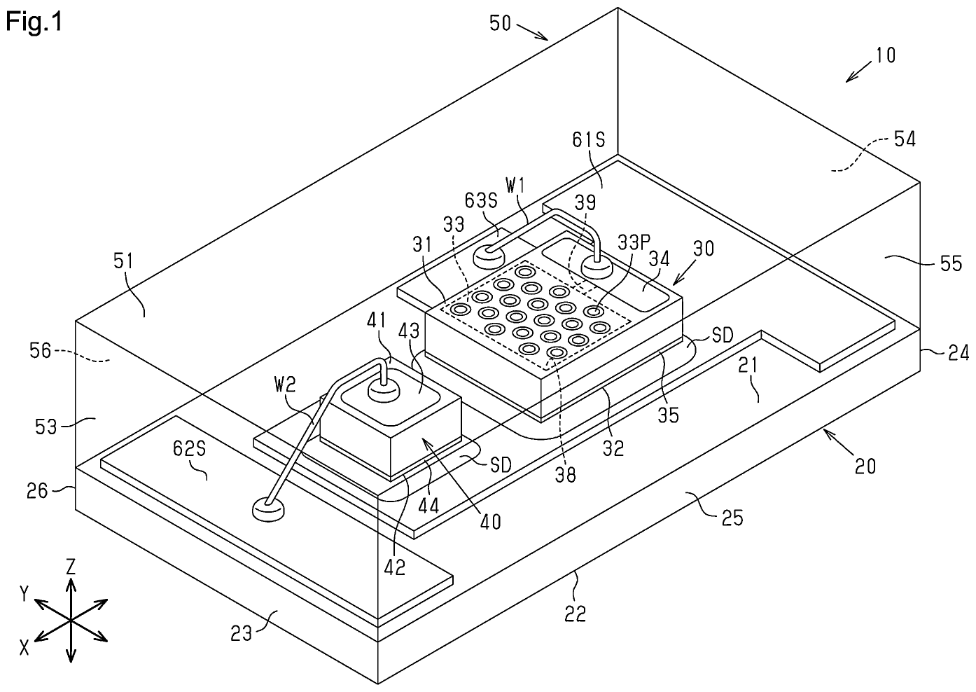

A semiconductor light emitting device 10 according to a first embodiment will now be described with reference to FIGS. 1 to 4.

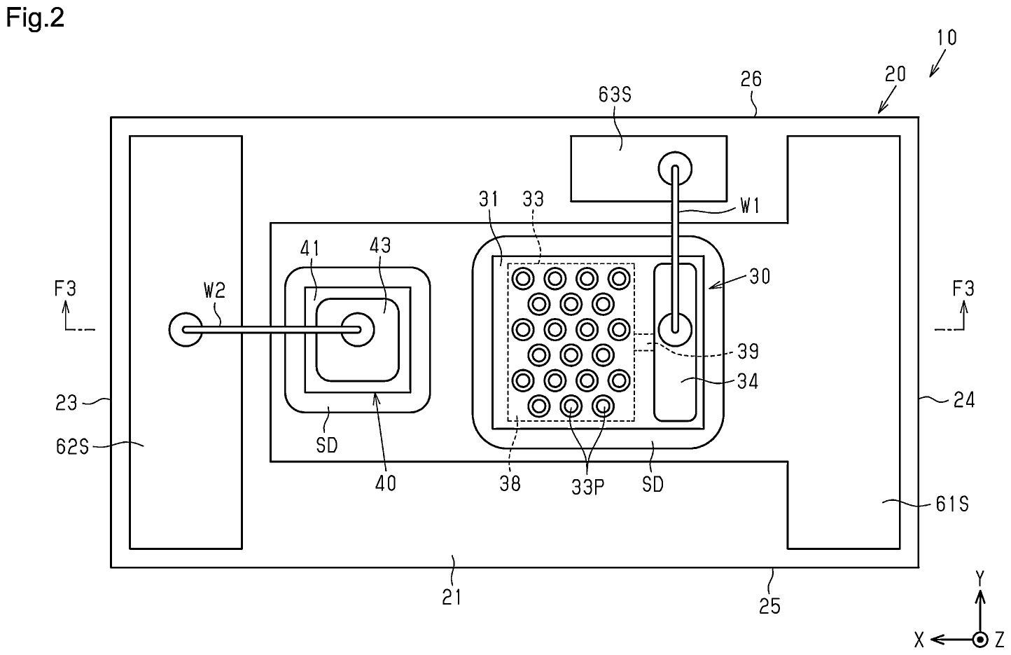

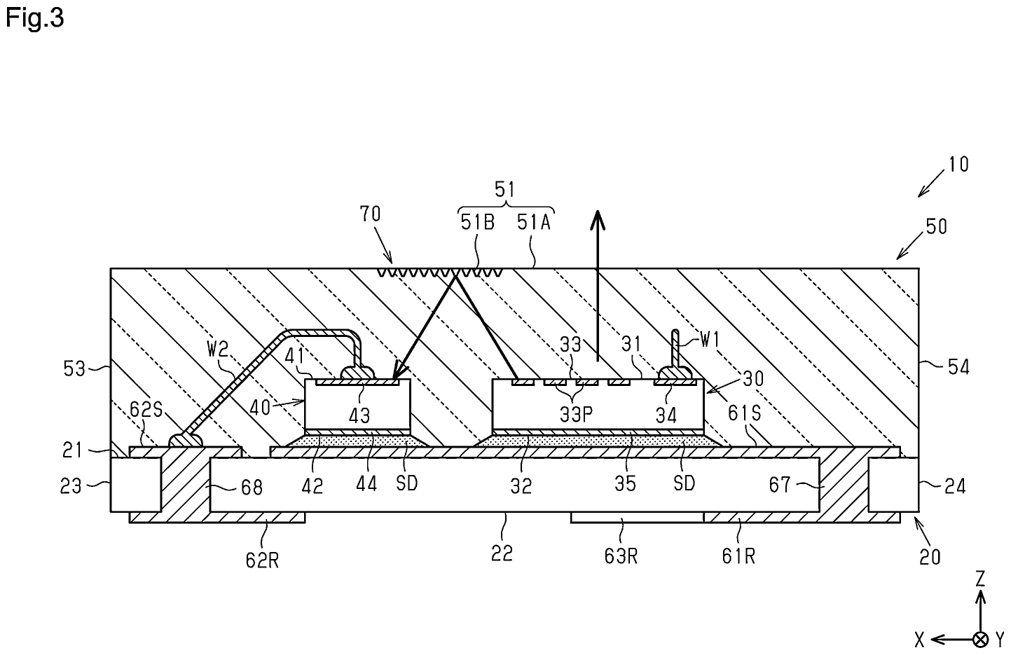

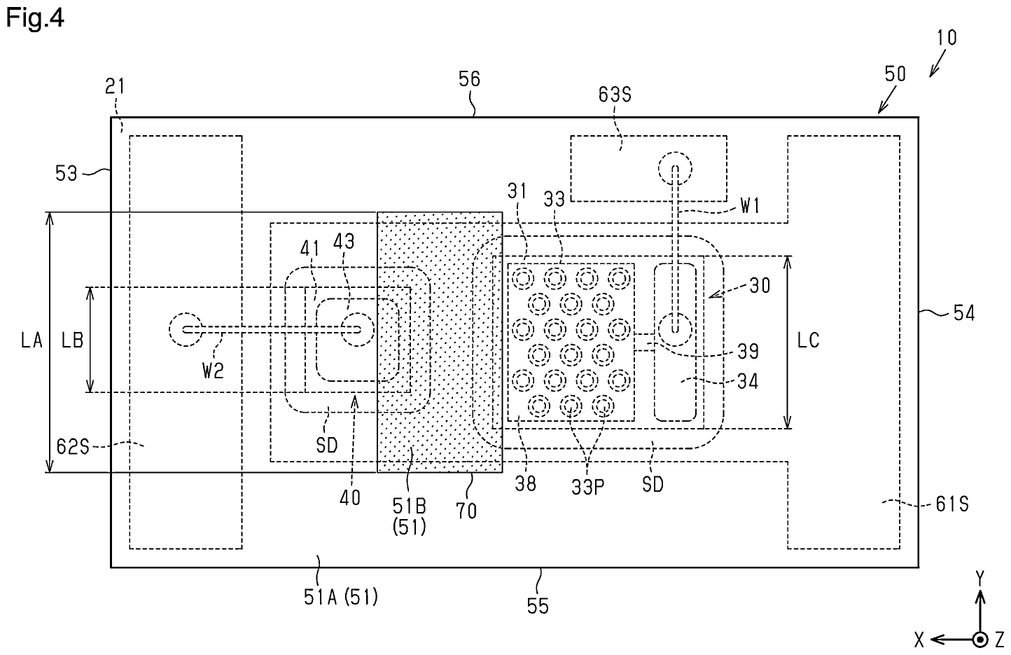

FIG. 1 illustrates a schematic perspective structure of the semiconductor light emitting device 10. FIG. 2 illustrates a schematic planar structure in a state in which a sealing member 50 to be described later is omitted from the semiconductor light emitting device 10. FIG. 3 illustrates a schematic cross-sectional structure of the semiconductor light emitting device 10 taken along line F3-F3 in FIG. 2. FIG. 4 illustrates a schematic planar structure of the semiconductor light emitting device 10. The term “plan view” used in the present disclosure refers to viewing the semiconductor light emitting device 10 in the Z direction of XYZ axes orthogonal to each other illustrated in FIG. 1.

### Overall Configuration of Semiconductor Light Emitting Device

As illustrated in FIG. 1, the semiconductor light emitting device 10 is formed in a rectangular flat plate shape with the Z direction as a thickness direction. The semiconductor light emitting device 10 includes a substrate 20, a surface emitting laser chip 30 and a light receiving chip 40 arranged on the substrate 20, and a sealing member 50 that seals the surface emitting laser chip 30 and the light receiving chip 40.

The substrate 20 is a component that supports the surface emitting laser chip 30 and the light receiving chip 40. The substrate 20 is formed in a rectangular flat plate shape in which the Z direction is the thickness direction. In the following description, “plan view” is synonymous with “as viewed from the thickness direction of the substrate”.

As illustrated in FIG. 2, the substrate 20 is formed in a rectangular shape in which the X direction is the longitudinal direction and the Y direction is the transverse direction in plan view. As illustrated in FIG. 1, the substrate 20 includes a substrate front surface 21, a substrate back surface 22 opposite to the substrate front surface 21 in the Z direction, and first to fourth substrate side surfaces 23 to 26 (see FIG. 2) connecting the substrate front surface 21 and the substrate back surface 22. The first substrate side surface 23 and the second substrate side surface 24 form opposite end surfaces of the substrate 20 in the X direction, and the third substrate side surface 25 and the fourth substrate side surface 26 form opposite end surfaces of the substrate 20 in the Y direction. The shape of the substrate 20 in plan view can be changed.

The substrate 20 is formed of, for example, an insulating material. The insulating material may be formed of, for example, a material containing an epoxy resin. As an example, the substrate 20 may be formed of a glass epoxy resin. The insulating material may be formed of, for example, a material containing ceramic. Examples of the ceramic-containing material include aluminum nitride (AlN) and alumina (Al₂O₃). When the substrate 20 is formed of a material containing ceramic, the heat dissipation performance of the substrate 20 is improved, so that it is possible to prevent the temperature of the semiconductor light emitting device 10 from becoming excessively high.

The surface emitting laser chip 30 is arranged on the substrate front surface 21. The surface emitting laser chip 30 is a laser diode that emits light of a predetermined wavelength band, and functions as a light source of the semiconductor light emitting device 10. The configuration of the surface emitting laser chip 30 is not particularly limited, but in the first embodiment, a vertical cavity surface emitting laser (VCSEL) is used.

The surface emitting laser chip 30 is formed in a rectangular flat plate shape in which the Z direction is the thickness direction. In one example, as illustrated in FIG. 2, the surface emitting laser chip 30 is formed in a rectangular shape in which the X direction is the longitudinal direction and the Y direction is the transverse direction in plan view. The shape of the surface emitting laser chip 30 in plan view can be changed.

As illustrated in FIG. 1, the surface emitting laser chip 30 has a first chip front surface 31 and a first chip back surface 32 facing opposite sides in the Z direction. The first chip front surface 31 is an example of a chip front surface of the surface emitting laser chip 30, and the first chip back surface 32 is an example of a chip back surface of the surface emitting laser chip 30. The first chip front surface 31 faces the same side as the substrate front surface 21, and the first chip back surface 32 faces the same side as the substrate back surface 22. On the first chip front surface 31, a light emitting surface 33 for emitting laser light and a front electrode 34 are formed. The front electrode 34 is an example of an electrode of the surface emitting laser chip 30. In plan view, the light emitting surface 33 and the front electrode 34 are arranged in the longitudinal direction (X direction) of the surface emitting laser chip 30. A back electrode 35 is formed on the first chip back surface 32. In one example, the back electrode 35 is formed over the entire first chip back surface 32. The surface emitting laser chip 30 is configured to emit laser light from the light emitting surface 33. The light emitting surface 33 is provided with multiple light emitting units 33P. Each light emitting unit 33P is configured to emit laser light in a direction perpendicular to the light emitting surface 33. The laser light emitted from each light emitting unit 33P may be visible light, or may be laser light having a longer wavelength than visible light such as ultraviolet light.

The region of the broken line frame defining the light emitting surface 33 is the same as the outer frame of the light emitting electrode 38 electrically connected to each light emitting unit 33P. That is, in plan view, a region surrounded by the outer frame of the light emitting electrode 38 is the light emitting surface 33. The light emitting electrode 38 is electrically connected to the front electrode 34. More specifically, the surface emitting laser chip 30 includes a connecting portion 39 that electrically connects the light emitting electrode 38 and the front electrode 34. The connecting portion 39 includes, for example, a wiring layer and a via. The light emitting electrode 38 may be integrally formed with the front electrode 34.

The light receiving chip 40 includes, for example, a photodiode. The light receiving chip 40 is arranged on the substrate front surface 21 to receive a part of the laser light of the surface emitting laser chip 30. The light receiving chip 40 is configured to output a signal corresponding to the intensity of the received light.

The light receiving chip 40 is formed in a rectangular flat plate shape in which the Z direction is the thickness direction. In one example, the light receiving chip 40 is formed in a square shape in plan view. In the example illustrated in FIG. 2, the dimension in the X direction and the dimension in the Y direction of the light receiving chip 40 are smaller than the dimension in the X direction and the dimension in the Y direction of the surface emitting laser chip 30. The shape and size of the light receiving chip 40 in plan view can be changed.

As illustrated in FIG. 1, the light receiving chip 40 has a second chip front surface 41 and a second chip back surface 42 facing opposite sides in the Z direction. The second chip front surface 41 faces the same side as the substrate front surface 21, and the second chip back surface 42 faces the same side as the substrate back surface 22. A front electrode 43 is formed on the second chip front surface 41. A back electrode 44 is formed on the second chip back surface 42. In the first embodiment, the second chip front surface 41 forms a light receiving surface. That is, the light receiving chip 40 is configured to generate a voltage signal corresponding to the intensity of the laser light incident on the second chip front surface 41.

As illustrated in FIG. 2, the surface emitting laser chip 30 and the light receiving chip 40 are arranged side by side in the X direction. The light receiving chip 40 is arranged on the substrate 20 to be separated from the surface emitting laser chip 30 in the X direction in plan view. In one example, the surface emitting laser chip 30 and the light receiving chip 40 are arranged to be separated from each other in the X direction in a state of being aligned with each other in the Y direction. The surface emitting laser chip 30 is arranged closer to the second substrate side surface 24 than the light receiving chip 40. In one example, the surface emitting laser chip 30 is arranged such that the light emitting surface 33 is closer to the light receiving chip 40 in plan view. It can also be said that the surface emitting laser chip 30 is arranged such that the front electrode 34 is on the opposite side of the light receiving chip 40 with respect to the light emitting surface 33. It can also be said that the surface emitting laser chip 30 is arranged such that the light emitting surface 33 is located between the light receiving chip 40 and the front electrode 34 in the X direction. The X direction is an example of a “first direction”.

As illustrated in FIG. 1, the sealing member 50 is provided on the substrate 20. The sealing member 50 is formed of a material through which the laser light of the surface emitting laser chip 30 can pass. The sealing member 50 is formed of, for example, a material containing at least one of a silicone resin, an epoxy resin, and an acrylic resin. In one example, the sealing member 50 is formed of a silicone resin.

The sealing member 50 is formed in a rectangular flat plate shape in which the Z direction is the thickness direction. The sealing member 50 has a sealing surface 51 facing the same side as the substrate front surface 21, and first to fourth sealing side surfaces 53 to 56 intersecting with the sealing surface 51.

The sealing surface 51 is a flat surface orthogonal to the thickness direction (Z direction) of the substrate 20. Therefore, the plan view can be paraphrased as viewed from a direction perpendicular to the sealing surface 51. The first to fourth sealing side surfaces 53 to 56 are, for example, orthogonal to the sealing surface 51. The first sealing side surface 53 and the second sealing side surface 54 form opposite end surfaces of the sealing member 50 in the X direction, and the third sealing side surface 55 and the fourth sealing side surface 56 form opposite end surfaces of the sealing member 50 in the Y direction. The first sealing side surface 53 faces the same side as the first substrate side surface 23, and the second sealing side surface 54 faces the same side as the second substrate side surface 24. The third sealing side surface 55 faces the same side as the third substrate side surface 25, and the fourth sealing side surface 56 faces the same side as the fourth substrate side surface 26. In one example, the first sealing side surface 53 and the first substrate side surface 23 are formed to be flush with each other, and the second sealing side surface 54 and the second substrate side surface 24 are formed to be flush with each other. The third sealing side surface 55 and the third substrate side surface 25 are formed to be flush with each other, and the fourth sealing side surface 56 and the fourth substrate side surface 26 are formed to be flush with each other. The laser light of the surface emitting laser chip 30 is emitted from the sealing member 50 via the sealing surface 51.

### Electrical Connection Configuration of Semiconductor Light Emitting Device

As illustrated in FIGS. 2 and 3, the semiconductor light emitting device 10 includes a first front electrode 61S, a second front electrode 62S, and a third front electrode 63S provided on the substrate front surface 21, a first back electrode 61R, a second back electrode 62R, and a third back electrode 63R provided on the substrate back surface 22, and a first via 67, a second via 68, and a third via (not illustrated) provided in the substrate 20. The first to third front electrodes 61S to 63S, the first to third back electrodes 61R to 63R, the first via 67, the second via 68, and the third via are formed of a material containing, for example, one or more appropriately selected from Ti (titanium), TiN (titanium nitride), Au (gold), Ag (silver), Cu (copper), Al (aluminum), and W (tungsten).

As illustrated in FIG. 2, the first front electrode 61S extends in the X direction from the second substrate side surface 24 toward the first substrate side surface 23 in plan view. In the example of FIG. 2, the first front electrode 61S is formed in a T-shape in plan view.

The second front electrode 62S is formed in a rectangular shape in which the Y direction is the longitudinal direction and the X direction is the transverse direction in plan view. The second front electrode 62S is arranged to be separated from the first front electrode 61S in the X direction. The second front electrode 62S is arranged at a position adjacent to the first substrate side surface 23 in the X direction in plan view.

The third front electrode 63S is formed in a rectangular shape in which the X direction is the longitudinal direction and the Y direction is the transverse direction in plan view. The third front electrode 63S is arranged at a position adjacent to the fourth substrate side surface 26 in the Y direction in plan view and closer to the second substrate side surface 24 than the center of the substrate front surface 21 in the X direction. The third front electrode 63S is arranged to be separated from both the first front electrode 61S and the second front electrode 62S.

Both the surface emitting laser chip 30 and the light receiving chip 40 are arranged on the first front electrode 61S. More specifically, as illustrated in FIG. 3, both the surface emitting laser chip 30 and the light receiving chip 40 are bonded to the first front electrode 61S by a conductive bonding material SD. As the conductive bonding material SD, for example, a solder paste, a silver paste, a gold paste, a copper paste, or the like may be used. As a result, both the back electrode 35 of the surface emitting laser chip 30 and the back electrode 44 of the light receiving chip 40 are electrically connected to the first front electrode 61S via the conductive bonding material SD.

A wire W1 is formed on the front electrode 34 of the surface emitting laser chip 30. The wire W1 is connected to the third front electrode 63S. As a result, the front electrode 34 of the surface emitting laser chip 30 and the third front electrode 63S are electrically connected via the wire W1. In the example illustrated in FIG. 2, the wire W1 is formed to extend in the Y direction in plan view.

A wire W2 is formed on the front electrode 43 of the light receiving chip 40. The wire W2 is connected to the second front electrode 62S. Thus, the front electrode 43 of the light receiving chip 40 and the second front electrode 62S are electrically connected via the wire W2. In the example illustrated in FIG. 2, the wire W2 is formed to extend in the X direction in plan view. The wires W1 and W2 are bonding wires formed by a wire bonding device, and are formed of a conductor containing Au, Al, Cu, or the like, for example.

As illustrated in FIG. 3, the first back electrode 61R and the second back electrode 62R are arranged to be separated from each other in the X direction. The third back electrode 63R is arranged to be separated from both the first back electrode 61R and the second back electrode 62R.

The first back electrode 61R is formed at an end portion closer to the second substrate side surface 24 among the opposite end portions of the substrate back surface 22 in the X direction. In plan view, the first back electrode 61R includes a portion overlapping with the first front electrode 61S.

The second back electrode 62R is formed at an end portion closer to the first substrate side surface 23 among the opposite end portions of the substrate back surface 22 in the X direction. In plan view, the second back electrode 62R includes a portion overlapping with the second front electrode 62S.

The third back electrode 63R is formed at a position closer to the second substrate side surface 24 than the center of the substrate back surface 22 in the X direction. In plan view, the third back electrode 63R includes a portion overlapping with the third front electrode 63S (see FIG. 2).

The first via 67 electrically connects the first front electrode 61S and the first back electrode 61R. The second via 68 electrically connects the second front electrode 62S and the second back electrode 62R. Although not illustrated, the third via electrically connects the third front electrode 63S and the third back electrode 63R. Each of the first via 67, the second via 68, and the third via extends through the substrate 20 in the Z direction. Multiple first vias 67, multiple second vias 68, and multiple third vias may be provided.

The first back electrode 61R is electrically connected to both the back electrode 35 of the surface emitting laser chip 30 and the back electrode 44 of the light receiving chip 40 via the first front electrode 61S and the first via 67. The second back electrode 62R is electrically connected to the front electrode 43 of the light receiving chip 40 via the second front electrode 62S and the second via 68. The third back electrode 63R is electrically connected to the front electrode 34 of the surface emitting laser chip 30 via the third front electrode 63S and the third via. As described above, the semiconductor light emitting device 10 is configured as a surface mount type package structure.

The semiconductor light emitting device 10 employs so-called auto power control (APC) driving in which a current to be supplied to the surface emitting laser chip 30 is controlled so that the light output of the surface emitting laser chip 30 is constant. More specifically, the control device that is provided outside the semiconductor light emitting device 10 and controls the current to be supplied to the surface emitting laser chip 30 receives a signal corresponding to the laser light of the surface emitting laser chip 30 received by the light receiving chip 40. In one example, the signal of the light receiving chip 40 is output to the control device via the second back electrode 62R. The control device is electrically connected to the second back electrode 62R to receive the signal of the light receiving chip 40. Then, the control device controls the current to be supplied to the surface emitting laser chip 30 according to a difference between the received signal and an output setting value to be a preset optical output. In one example, the controller controls the current to be supplied to the surface emitting laser chip 30 so that the level of the received signal matches the output set value.

### Reflecting Portion

As illustrated in FIGS. 3 and 4, the semiconductor light emitting device 10 includes a reflecting portion 70 that reflects a part of the laser light of the surface emitting laser chip 30 toward the light receiving chip 40. The reflecting portion 70 is provided in the sealing member 50. The light receiving chip 40 is arranged at a position to receive at least a part of the light reflected by the reflecting portion 70.

In the first embodiment, the reflecting portion 70 includes irregularities formed on a part of the sealing surface 51 of the sealing member 50. More specifically, as illustrated in FIG. 4, the sealing surface 51 of the sealing member 50 includes a flat surface 51A and a rough surface 51B that is rougher than the flat surface 51A. In the first embodiment, the reflecting portion 70 includes the rough surface 51B. The sealing member 50 is formed by, for example, molding. The rough surface 51B is formed during molding of the sealing member 50. More specifically, an uneven region for forming the rough surface 51B is formed in a mold used for molding. Accordingly, when the mold is separated from the sealing member 50 after the molding of the sealing member 50, the rough surface 51B is formed on the sealing member 50.

In plan view, the reflecting portion 70 is formed between the surface emitting laser chip 30 and the light receiving chip 40 in the X direction. In one example, the reflecting portion 70 includes a portion overlapping with the light receiving chip 40 in plan view. In the example illustrated in FIG. 4, the reflecting portion 70 includes a portion overlapping with an end portion closer to the surface emitting laser chip 30 among the opposite end portions of the light receiving chip 40 in the X direction in plan view. Furthermore, in the example illustrated in FIG. 4, the reflecting portion 70 is formed at a position not overlapping with the light emitting surface 33 of the surface emitting laser chip 30 in plan view. More specifically, an end portion closer to the surface emitting laser chip 30 among the opposite end portions of the reflecting portion 70 in the X direction is arranged at a position adjacent to the light emitting surface 33 of the surface emitting laser chip 30 in the X direction. On the other hand, the reflecting portion 70 includes a portion overlapping with the first chip front surface 31 of the surface emitting laser chip 30 in plan view. As described above, the reflecting portion 70 is provided to extend over the surface emitting laser chip 30 and the light receiving chip 40 in the X direction in plan view.

The shape of the reflecting portion 70 in a plan view is, for example, a rectangular shape. In the example illustrated in FIG. 4, the shape of the reflecting portion 70 in plan view is a rectangular shape in which the X direction is the transverse direction and the Y direction is the longitudinal direction. The area of the reflecting portion 70 in plan view is larger than the area of the second chip front surface 41 of the light receiving chip 40. In one example, as illustrated in FIG. 4, a dimension LA of the reflecting portion 70 in the Y direction is larger than a dimension LB of the second chip front surface 41 of the light receiving chip 40 in the Y direction. In one example, the dimension LA is larger than a dimension LC of the surface emitting laser chip 30 in the Y direction. The shape and size of the reflecting portion 70 in plan view can be changed.

### Operation

Operation of the semiconductor light emitting device 10 according to the first embodiment will now be described.

In the surface emitting laser chip 30 such as the VCSEL, the output of the laser light changes according to the temperature of the surface emitting laser chip 30. More specifically, the output of the laser light of the surface emitting laser chip 30 decreases as the temperature of the surface emitting laser chip 30 increases. On the other hand, in the semiconductor light emitting device 10, the output of the laser light is required to be constant regardless of the temperature.

In this regard, in the semiconductor light emitting device 10, the light receiving chip 40 receives a part of the laser light emitted from the surface emitting laser chip 30, so that the output of the laser light emitted from the surface emitting laser chip 30 is obtained, and then, so-called APC driving is performed in which the output of the laser light from the surface emitting laser chip 30 is controlled so as to be a predetermined laser light output. That is, the amount of current supplied to the surface emitting laser chip 30 is controlled according to the difference between the output of the laser light received by the light receiving chip 40 and the output setting value.

In order to perform such APC driving, in the semiconductor light emitting device 10, the reflecting portion 70 that reflects a part of the laser light from the surface emitting laser chip 30 toward the light receiving chip 40 is provided in the sealing member 50. By arranging the light receiving chip 40 at a position to receive at least a part of the reflected light by the reflecting portion 70, the light receiving chip 40 readily receives a part of the laser light from the surface emitting laser chip 30. As a result, the current to be supplied to the surface emitting laser chip 30 is controlled based on the APC drive.

### Advantages

According to the semiconductor light emitting device 10 of the first embodiment, the following advantages are obtained.

(1-1) The semiconductor light emitting device 10 includes the surface emitting laser chip 30 having the light emitting surface 33 and configured to emit laser light from the light emitting surface 33, the light receiving chip 40, the sealing member 50 that is formed of a material through which the laser light can pass and seals the surface emitting laser chip 30 and the light receiving chip 40, and the reflecting portion 70 that is provided in the sealing member 50 and reflects a part of the laser light toward the light receiving chip 40. The light receiving chip 40 is arranged at a position to receive at least a part of the light reflected by the reflecting portion 70.

According to this configuration, a part of the laser light from the surface emitting laser chip 30 is reflected by the reflecting portion 70 toward the light receiving chip 40, and the light receiving chip 40 is arranged at the position to receive at least a part of the reflected light reflected by the reflecting portion 70, so that the light receiving chip 40 readily receives a part of the laser light from the surface emitting laser chip 30. Therefore, when the semiconductor light emitting device 10 is controlled by APC driving, the output of the laser light of the surface emitting laser chip 30 can be controlled to be a preset value based on the amount of light received by the light receiving chip 40.

In addition, since the surface emitting laser chip 30 and the light receiving chip 40 are sealed by the sealing member 50, it is possible to suppress adhesion of foreign matter such as moisture and/or dust to the surface emitting laser chip 30 and the light receiving chip 40. In addition, for example, as compared with a configuration in which the surface emitting laser chip 30 and the light receiving chip 40 are sealed by a side wall provided on the substrate 20 and surrounding the surface emitting laser chip 30 and the light receiving chip 40 and a translucent cap covering the opening of the side wall instead of the sealing member 50, the configuration including the sealing member 50 simplifies the manufacturing process and reduce the manufacturing cost.

(1-2) The reflecting portion 70 includes irregularities formed on a part of the sealing surface 51 of the sealing member 50.

According to this configuration, since the reflecting portion 70 is formed integrally with the sealing member 50 without being provided as a separate member from the sealing member 50, the manufacturing costs are reduced.

(1-3) The sealing surface 51 of the sealing member 50 includes the flat surface 51A and the rough surface 51B rougher than the flat surface (51A). The reflecting portion (70) includes the rough surface (51B).

According to this configuration, a part of the laser light from the surface emitting laser chip 30 is diffusely reflected (irregularly reflected) on the rough surface 51B, so that the light receiving chip 40 receives a part of the reflected light from the rough surface 51B. On the other hand, since the laser light emitted from the surface emitting laser chip 30 passes through the flat surface 51A, diffusion of the laser light is suppressed. Therefore, it is possible to limit a decrease in directivity of the surface emitting laser chip 30.

(1-4) In plan view, the light emitting surface 33 of the surface emitting laser chip 30 and the second chip front surface 41 as a light receiving surface of the light receiving chip 40 are arranged to be separated from each other in an X direction. The reflecting portion 70 is formed between the light emitting surface 33 and the second chip front surface 41 in the X direction.

According to this configuration, the reflecting portion 70 readily reflects a part of the laser light from the surface emitting laser chip 30. Therefore, the light receiving chip 40 readily receives a part of the laser light from the surface emitting laser chip 30.

(1-5) The reflecting portion 70 is provided to extend over the surface emitting laser chip 30 and the light receiving chip 40 in the X direction in plan view.

According to this configuration, the reflecting portion 70 more readily reflects a part of the laser light from the surface emitting laser chip 30. Therefore, the light receiving chip 40 further readily receives a part of the laser light from the surface emitting laser chip 30.

(1-6) On the first chip front surface 31 of the surface emitting laser chip 30, the light emitting surface 33 and the front electrode 34 formed to be separated from the light emitting surface 33 in the X direction in plan view are formed. The light receiving chip 40 is arranged on the side opposite to the front electrode 34 with respect to the light emitting surface 33 in the X direction.

According to this configuration, the distance between the light emitting surface 33 of the surface emitting laser chip 30 and the second chip front surface 41 (light receiving surface) of the light receiving chip 40 is shortened in the X direction. Therefore, the light receiving chip 40 readily receives a part of the laser light from the surface emitting laser chip 30.

(1-7) The shape of the reflecting portion 70 is a rectangular shape in plan view.

According to this configuration, as compared with a case in which the shape of the reflecting portion 70 in plan view is a circular shape, even if the position of the reflecting portion 70 is shifted with respect to the surface emitting laser chip 30 and the light receiving chip 40 in plan view, a part of the laser light from the surface emitting laser chip 30 is readily reflected.

(1-8) In plan view, the dimension LA of the reflecting portion 70 in the Y direction is larger than the dimension LB of the light receiving chip 40 in the Y direction.

According to this configuration, even if the position of the reflecting portion 70 is shifted in the Y direction with respect to the light receiving chip 40, the reflected light from the reflecting portion 70 is readily incident on the second chip front surface 41 of the light receiving chip 40.

(1-9) In plan view, the dimension LA of the reflecting portion 70 in the Y direction is larger than a dimension LC of the surface emitting laser chip 30 in the Y direction.

According to this configuration, even if the position of the reflecting portion 70 is shifted in the Y direction with respect to the surface emitting laser chip 30, a part of the laser light from the surface emitting laser chip 30 is reflected by the reflecting portion 70.

### Second Embodiment

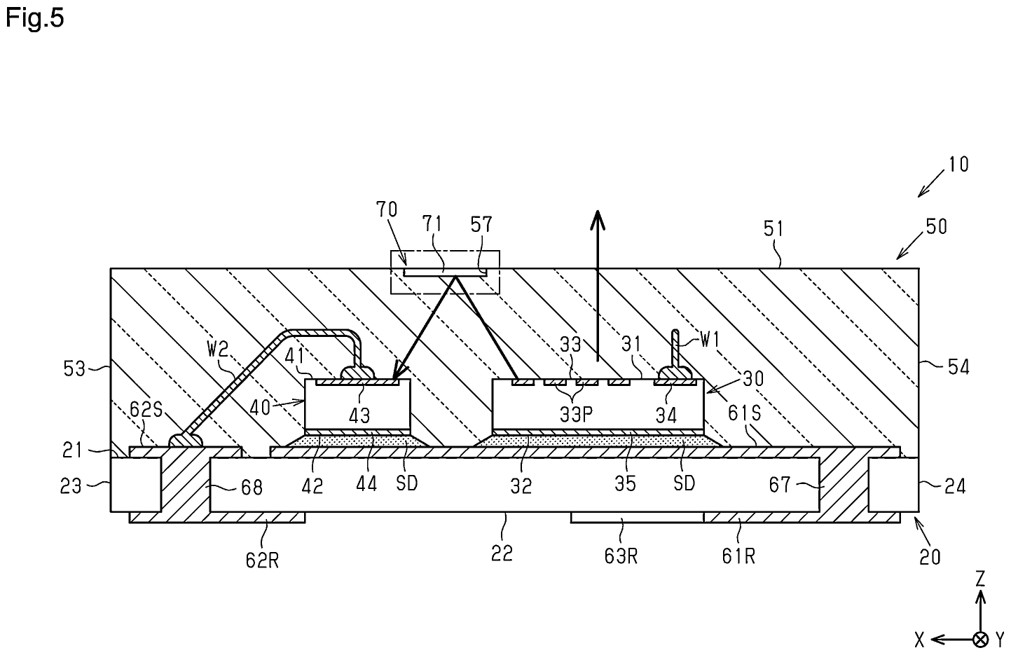

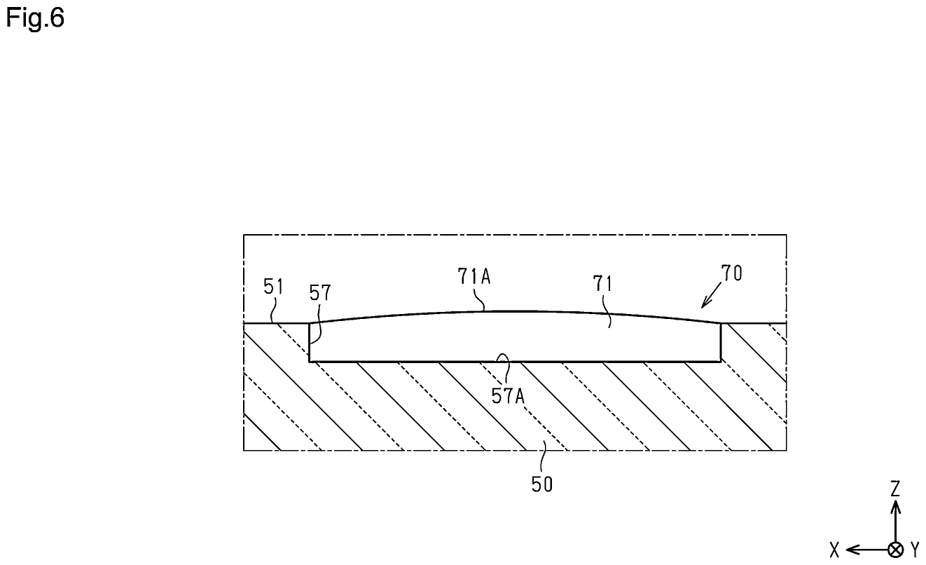

A semiconductor light emitting device 10 according to a second embodiment will now be described with reference to FIGS. 5 and 6. The semiconductor light emitting device 10 of the second embodiment is different from the semiconductor light emitting device 10 of the first embodiment in the configuration of the reflecting portion 70. Hereinafter, differences from the semiconductor light emitting device 10 according to the first embodiment will be described in detail, and the same reference numerals are given to components common to the semiconductor light emitting device 10 of the first embodiment, and a detailed description thereof will be omitted. FIG. 5 illustrates a schematic cross-sectional structure of the semiconductor light emitting device 10 cut along the XZ plane. FIG. 6 illustrates a schematic cross-sectional structure in which the reflecting portion 70 and its periphery in FIG. 5 are enlarged.

As illustrated in FIGS. 5 and 6, in the semiconductor light emitting device 10 of the second embodiment, the reflecting portion 70 includes a reflecting layer 71 that reflects the laser light of the surface emitting laser chip 30 toward the light receiving chip 40 instead of the rough surface 51B (see FIG. 3) of the sealing member 50. The reflecting layer 71 is provided on the sealing member 50.

A recess 57 is provided in a region of the sealing member 50 where the reflecting portion 70 is formed. The recess 57 is formed in a part of the sealing surface 51 of the sealing member 50. The recess 57 is recessed in the Z direction from the sealing surface 51 toward the substrate 20. In the example illustrated in FIGS. 5 and 6, a bottom surface 57A of the recess 57 is formed by a flat surface orthogonal to the Z direction. That is, the bottom surface 57A is parallel to the sealing surface 51 of the sealing member 50.

The reflecting layer 71 is provided in the recess 57. That is, the reflecting layer 71 is provided as a member different from the sealing member 50. As the reflecting layer 71, for example, a white reflecting material may be used. The reflecting material may be formed of, for example, a material containing a silicone resin. The reflecting material may be formed of a reflective paint. The reflecting layer 71 is formed by applying a reflecting material to the recess 57, for example. The reflecting layer 71 may be, for example, a metal film such as Al. In this case, the reflecting layer 71 is formed by depositing a metal film on the recess 57. As illustrated in FIG. 6, the reflecting layer 71 may be formed to protrude from the sealing surface 51 of the sealing member 50. In the example illustrated in FIG. 6, the center of the reflecting layer 71 in the X direction is formed to be thick. More specifically, the surface 71A of the reflecting layer 71 is formed in a curved convex shape to protrude from the sealing surface 51 toward the center in the X direction.

The shape of the bottom surface 57A of the recess 57 can be changed. In one example, the bottom surface 57A may be formed to have a curved convex shape toward the sealing surface 51 toward the center in the X direction. In this case, the reflecting layer 71 may be formed in a curved convex shape according to the shape of the bottom surface 57A. Furthermore, in one example, the bottom surface 57A may be formed to have a curved concave shape toward the substrate 20 (see FIG. 5) toward the center in the X direction. In this case, the reflecting layer 71 may be formed in a curved concave shape according to the shape of the bottom surface 57A.

### Advantages

According to the semiconductor light emitting device 10 of the second embodiment, the following advantages are obtained in addition to the advantages of (1-1) and (1-4) to (1-9) of the first embodiment.

(2-1) The sealing member 50 includes the sealing surface 51 through which the laser light passes, and a recess 57 in which a part of the sealing surface 51 is recessed toward the substrate 20. The reflecting portion 70 includes the reflecting layer 71 provided in the recess 57.

According to this configuration, since the reflecting layer 71 is provided as a separate member from the sealing member 50, the reflectance of the laser light can be adjusted according to the material constituting the reflecting layer 71.

In addition, when the recess 57 is simultaneously formed when the sealing member 50 is formed by the mold, that is, when the recess 57 is formed by the mold, each of the position of the recess 57 with respect to the sealing member 50 and the dimension in the X direction and the dimension in the Y direction of the recess 57 is set with high accuracy. Therefore, variations in the dimension in the X direction and the dimension in the Y direction of the reflecting layer 71 provided in the recess 57 are reduced. Therefore, it is possible to suppress the positional deviation of the reflecting layer 71 with respect to the surface emitting laser chip 30 and the light receiving chip 40.

### Third Embodiment

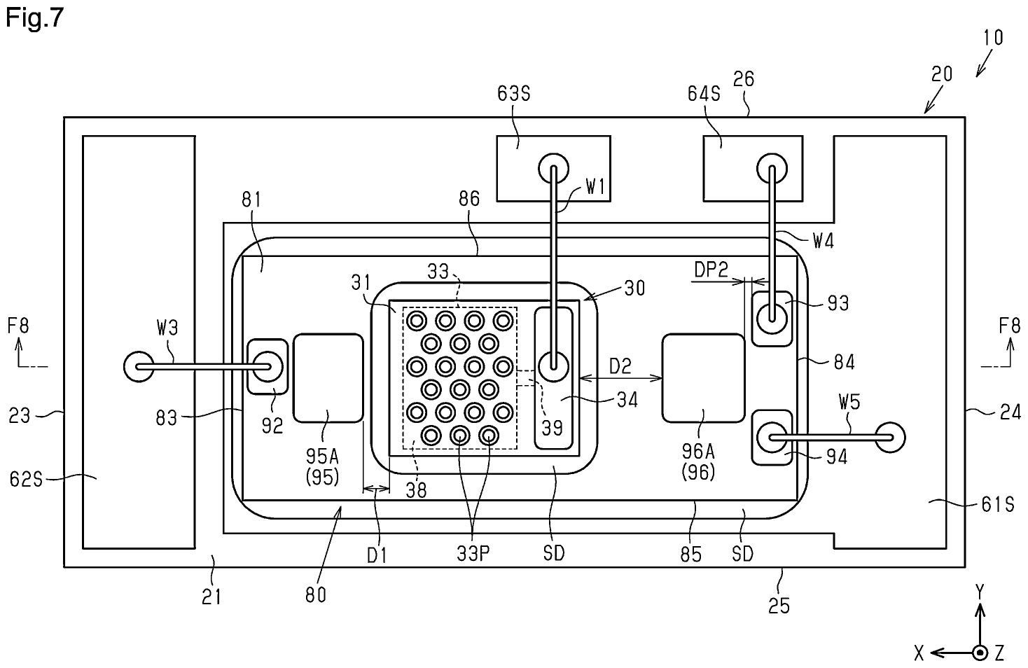

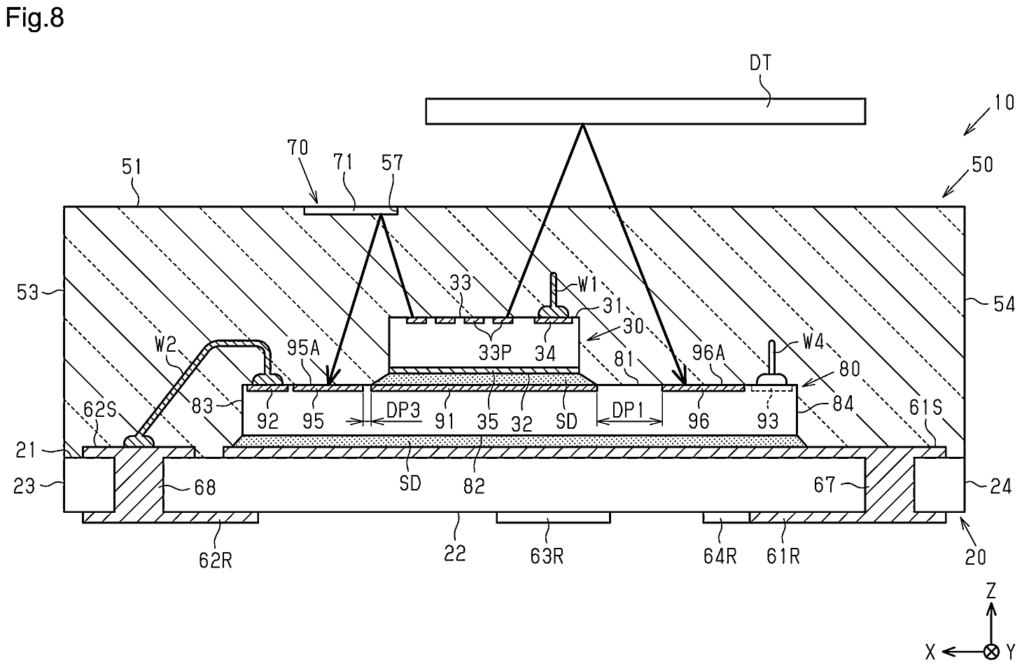

A semiconductor light emitting device 10 according to a third embodiment will now be described with reference to FIGS. 7 and 8. The semiconductor light emitting device 10 of the third embodiment is different from the semiconductor light emitting device 10 of the second embodiment mainly in the configuration of the light receiving chip and the arrangement of the light receiving chip and the surface emitting laser chip 30. Hereinafter, differences from the semiconductor light emitting device 10 according to the second embodiment will be described in detail, and the same reference numerals are given to components common to the semiconductor light emitting device 10 of the second embodiment, and a detailed description thereof will be omitted. FIG. 7 illustrates a schematic planar structure in a state in which the sealing member 50 is omitted from the semiconductor light emitting device 10. FIG. 8 illustrates a schematic cross-sectional structure of the semiconductor light emitting device 10 taken along line F8-F8 in FIG. 7.

As illustrated in FIG. 7, the semiconductor light emitting device 10 of the third embodiment includes a light receiving chip 80 instead of the light receiving chip 40 (see FIG. 5).

As illustrated in FIGS. 7 and 8, the light receiving chip 80 is formed in a rectangular flat plate shape in which the Z direction is the thickness direction. The dimension in the X direction and the dimension in the Y direction of the light receiving chip 80 are larger than the dimension in the X direction and the dimension in the Y direction of the surface emitting laser chip 30. The light receiving chip 80 is bonded to the first front electrode 61S by, for example, the conductive bonding material SD.

The light receiving chip 80 includes a chip front surface 81 and a chip back surface 82 (see FIG. 8) facing opposite sides in the Z direction, and first to fourth chip side surfaces 83 to 86 connecting the chip front surface 81 and the chip back surface 82. The first chip side surface 83 and the second chip side surface 84 form the opposite end surfaces of the light receiving chip 80 in the X direction, and the third chip side surface 85 and the fourth chip side surface 86 form the opposite end surfaces of the light receiving chip 80 in the Y direction. The chip front surface 81 faces the same side as the substrate front surface 21, and the chip back surface 82 faces the same side as the substrate back surface 22. The first chip side surface 83 faces the same side as the first substrate side surface 23, and the second chip side surface 84 faces the same side as the second substrate side surface 24. The third chip side surface 85 faces the same side as the third substrate side surface 25, and the fourth chip side surface 86 faces the same side as the fourth substrate side surface 26. The Z direction is an example of a “direction perpendicular to the chip front surface”. Therefore, the plan view also includes the meaning of “as viewed from a direction perpendicular to the chip front surface”.

The light receiving chip 80 includes a light receiving element 95, a detection light receiving element 96, a first electrode 91, a second electrode 92, a third electrode 93, and a fourth electrode 94. The light receiving element 95, the detection light receiving element 96, and the first to fourth electrodes 91 to 94 are formed on the chip front surface 81.

The first electrode 91 is formed at the center of the chip front surface 81 in the X direction. The first electrode 91 is an electrode on which the surface emitting laser chip 30 is mounted. The area of the first electrode 91 in plan view is larger than the areas of the second to fourth electrodes 92 to 94.

The second electrode 92 is formed at an end portion closer to the first chip side surface 83 among the opposite end portions of the chip front surface 81 in the X direction. The third electrode 93 and the fourth electrode 94 are formed at end portions closer to the second chip side surface 84 among the opposite end portions of the chip front surface 81 in the X direction. The third electrode 93 and the fourth electrode 94 are arranged to be separated from each other in the Y direction. The fourth electrode 94 is electrically connected to the first electrode 91 in the light receiving chip 80.

As illustrated in FIG. 8, the light receiving element 95 includes, for example, a photodiode. The light receiving element 95 is configured to receive at least a part of the reflected light obtained by reflecting the laser light of the surface emitting laser chip 30 by the reflecting portion 70. The light receiving element 95 is formed between the first electrode 91 and the second electrode 92 in the X direction.

The light receiving element 95 includes a light receiving surface 95A, and a first element electrode and a second element electrode. The first element electrode forms one of an anode and a cathode of the photodiode, and the second element electrode forms the other of the anode and the cathode of the photodiode. The second electrode 92 is electrically connected to the first element electrode of the light receiving element 95 in the light receiving chip 80. The fourth electrode 94 is electrically connected to the second element electrode of the light receiving element 95 in the light receiving chip 80.

The detection light receiving element 96 includes, for example, a photodiode. The detection light receiving element 96 is configured to receive at least a part of the reflected light that is the laser light emitted from the surface emitting laser chip 30 and reflected by the object DT. The detection light receiving element 96 is arranged between the first electrode 91, the third electrode 93, and the fourth electrode 94 in the X direction. The detection light receiving element 96 is arranged closer to the third electrode 93 and the fourth electrode 94 than the first electrode 91, for example, as viewed from the Y direction. That is, a distance DP1 between the detection light receiving element 96 and the first electrode 91 in the X direction is larger than a distance DP2 (see FIG. 7) between the detection light receiving element 96 and the third electrode 93 (fourth electrode 94) in the X direction. In one example, the distance DP1 between the detection light receiving element 96 and the first electrode 91 in the X direction is larger than a distance DP3 between the light receiving element 95 and the first electrode 91 in the X direction. Each of the distances DP1, DP2, and DP3 can be changed.

The detection light receiving element 96 includes a detection surface 96A, and a first element electrode and a second element electrode. The first element electrode forms one of an anode and a cathode of the photodiode, and the second element electrode forms the other of the anode and the cathode of the photodiode. The third electrode 93 is electrically connected to the first element electrode of the detection light receiving element 96 in the light receiving chip 80. The fourth electrode 94 is electrically connected to the second element electrode of the detection light receiving element 96 in the light receiving chip 80.

As illustrated in FIG. 8, the surface emitting laser chip 30 is bonded to the chip front surface 81. More specifically, the surface emitting laser chip 30 is bonded to the first electrode 91 formed on the chip front surface 81. The surface emitting laser chip 30 is electrically connected to the first electrode 91 by the conductive bonding material SD. Therefore, the back electrode 35 of the surface emitting laser chip 30 is electrically connected to the first electrode 91 via the conductive bonding material SD.

As illustrated in FIG. 7, the surface emitting laser chip 30 is arranged at a position different from the light receiving element 95 in plan view. More specifically, the surface emitting laser chip 30 is arranged closer to the second chip side surface 84 than the light receiving element 95. It can also be said that the surface emitting laser chip 30 is arranged between the light receiving element 95 and the detection light receiving element 96 in the X direction in plan view. In other words, it can be said that the light receiving element 95 and the detection light receiving element 96 are dispersedly formed on the opposite sides of the surface emitting laser chip 30 in the X direction. Therefore, it can be said that the detection light receiving element 96 is arranged on the side opposite to the light receiving element 95 with respect to the surface emitting laser chip 30 in the X direction. In plan view, a distance D1 between the surface emitting laser chip 30 and the light receiving element 95 in the X direction is smaller than a distance D2 between the surface emitting laser chip 30 and the detection light receiving element 96 in the X direction.

The front electrode 34 of the surface emitting laser chip 30 is arranged closer to the detection light receiving element 96 than the light emitting surface 33 in plan view. Therefore, it can be said that the light receiving element 95 is arranged on the side opposite to the front electrode 34 with respect to the light emitting surface 33 in the X direction.

As illustrated in FIG. 8, the light emitting surface 33 of the surface emitting laser chip 30 is arranged closer to the sealing surface 51 than the light receiving surface 95A of the light receiving element 95 and the detection surface 96A of the detection light receiving element 96 in the Z direction. In addition, the first chip back surface 32 of the surface emitting laser chip 30 is arranged closer to the sealing surface 51 than the light receiving surface 95A of the light receiving element 95 and the detection surface 96A of the detection light receiving element 96 in the Z direction.

As illustrated in FIG. 7, the semiconductor light emitting device 10 includes a first front electrode 61S, a second front electrode 62S, a third front electrode 63S, and a fourth front electrode 64S formed on the substrate front surface 21. The first front electrode 61S, the second front electrode 62S, the third front electrode 63S, and the fourth front electrode 64S are arranged to be separated from each other. The arrangement of the first front electrode 61S and the second front electrode 62S is the same as that of the first embodiment. The shape and size of the second front electrode 62S are the same as those of the first embodiment.

The third front electrode 63S and the fourth front electrode 64S are arranged closer to the fourth substrate side surface 26 than the light receiving chip 80 in plan view. The third front electrode 63S and the fourth front electrode 64S are arranged at the same position in the Y direction and to be separated from each other in the X direction. The third front electrode 63S is arranged closer to the first substrate side surface 23 than the fourth front electrode 64S. The shape of the third front electrode 63S and the fourth front electrode 64S in plan view is a rectangular shape in which the X direction is the longitudinal direction and the Y direction is the transverse direction.

A wire W1 is formed on the front electrode 34 of the surface emitting laser chip 30. The wire W1 is connected to the third front electrode 63S. As a result, the front electrode 34 of the surface emitting laser chip 30 and the third front electrode 63S are electrically connected via the wire W1. In the example illustrated in FIG. 7, the wire W1 is formed to extend in the Y direction in plan view.

A wire W3 is formed on the second electrode 92. The wire W3 is connected to the second front electrode 62S. Thus, the first element electrode of the light receiving element 95 and the second front electrode 62S are electrically connected via the wire W3 and the second electrode 92. In the example illustrated in FIG. 7, the wire W3 is formed to extend in the X direction in plan view.

A wire W4 is formed on the third electrode 93. The wire W4 is connected to the fourth front electrode 64S. Thus, the first element electrode of the detection light receiving element 96 and the second front electrode 62S are electrically connected via the wire W4 and the third electrode 93. In the example illustrated in FIG. 7, the wire W4 is formed to extend in the X direction in plan view.

A wire W5 is formed on the fourth electrode 94. The wire W5 is connected to the first front electrode 61S. As a result, the back electrode 35 of the surface emitting laser chip 30, the second element electrode of the light receiving element 95, and the second element electrode of the detection light receiving element 96 are electrically connected to the first front electrode 61S via the wire W5 and the fourth electrode 94. The wires W1 and W3 to W5 are bonding wires formed by a wire bonding device, and are formed of a conductor containing Au, Al, Cu, or the like, for example.

As illustrated in FIG. 8, the semiconductor light emitting device 10 includes a first back electrode 61R, a second back electrode 62R, a third back electrode 63R, and a fourth back electrode 64R formed on the substrate back surface 22, and a first via 67, a second via 68, a third via (not shown), and a fourth via (not shown) formed on the substrate 20. The arrangement, shape, and size of the first front electrode 61S, the second front electrode 62S, the first via 67, and the second via 68 are the same as those in the first embodiment.

The third back electrode 63R is formed at a position closer to the second substrate side surface 24 than the center of the substrate back surface 22 in the X direction. In plan view, the third back electrode 63R includes a portion overlapping with the third front electrode 63S (see FIG. 7).

The fourth back electrode 64R is formed at a position closer to the second substrate side surface 24 than the third back electrode 63R. In plan view, the fourth back electrode 64R includes a portion overlapping with the fourth front electrode 64S (see FIG. 7).

Although not illustrated, the third via electrically connects the third front electrode 63S and the third back electrode 63R. The fourth via electrically connects the fourth front electrode 64S and the fourth back electrode 64R. Each of the third via and the fourth via extends through the substrate 20 in the Z direction. Multiple first vias 67, multiple second vias 68, multiple third vias, and multiple fourth vias may be provided.

The reflecting portion 70 is formed between the surface emitting laser chip 30 and the light receiving element 95 in the X direction in plan view. In one example, the reflecting portion 70 includes a portion overlapping with the light receiving element 95 in plan view. The reflecting portion 70 includes a portion overlapping with an end portion closer to the surface emitting laser chip 30 among the opposite end portions of the light receiving element 95 in the X direction in plan view. In the example illustrated in FIG. 8, the reflecting portion 70 is formed to overlap with most of the light receiving element 95 in plan view. Furthermore, in the example illustrated in FIG. 8, the reflecting portion 70 is formed at a position not overlapping with the light emitting surface 33 of the surface emitting laser chip 30 in plan view. More specifically, an end portion closer to the surface emitting laser chip 30 among the opposite end portions of the reflecting portion 70 in the X direction is arranged at a position adjacent to the light emitting surface 33 of the surface emitting laser chip 30 in the X direction. On the other hand, the reflecting portion 70 is formed at a position overlapping with an end portion closer to the light receiving element 95 among the opposite end portions of the first chip front surface 31 of the surface emitting laser chip 30 in the X direction. The configuration of the reflecting portion 70 and the configuration of the sealing member 50 related to the reflecting portion 70 are similar to those of the second embodiment. The reflecting portion 70 is larger than the area of the light receiving surface 95A of the light receiving element 95 in plan view.

### Advantages

According to the semiconductor light emitting device 10 of the third embodiment, the following advantages are obtained.

(3-1) The light receiving chip 80 includes the light receiving element 95 and the chip front surface 81. The chip front surface 81 includes the light receiving surface 95A of the light receiving element 95. The surface emitting laser chip 30 is bonded to the chip front surface 81 and is arranged at a position different from the light receiving surface 95A in plan view. The light receiving chip 80 further includes the detection light receiving element 96 that is configured to receive reflected light that is the laser light emitted from the surface emitting laser chip 30 and reflected by an object DT. The detection light receiving element 96 is arranged on the side opposite to the light receiving element 95 with respect to the surface emitting laser chip 30 in the X direction.

According to this configuration, since the semiconductor light emitting device 10 includes the surface emitting laser chip 30, the light receiving element 95, and the detection light receiving element 96, for example, the number of the components is reduced as compared with a configuration in which the detection light receiving element 96 is arranged outside the semiconductor light emitting device 10.

In addition, since the surface emitting laser chip 30 is bonded to the chip front surface 81 of the light receiving chip 80, it is possible to prevent the detection light receiving element 96 from receiving light leaking from the surface emitting laser chip 30.

In addition, since the light receiving element 95 and the detection light receiving element 96 are dispersedly arranged on the opposite sides of the surface emitting laser chip 30 in the X direction, it is possible to prevent the light receiving element 95 from receiving the reflected light that is the laser light emitted from the surface emitting laser chip 30 and reflected by the object DT.

### Fourth Embodiment

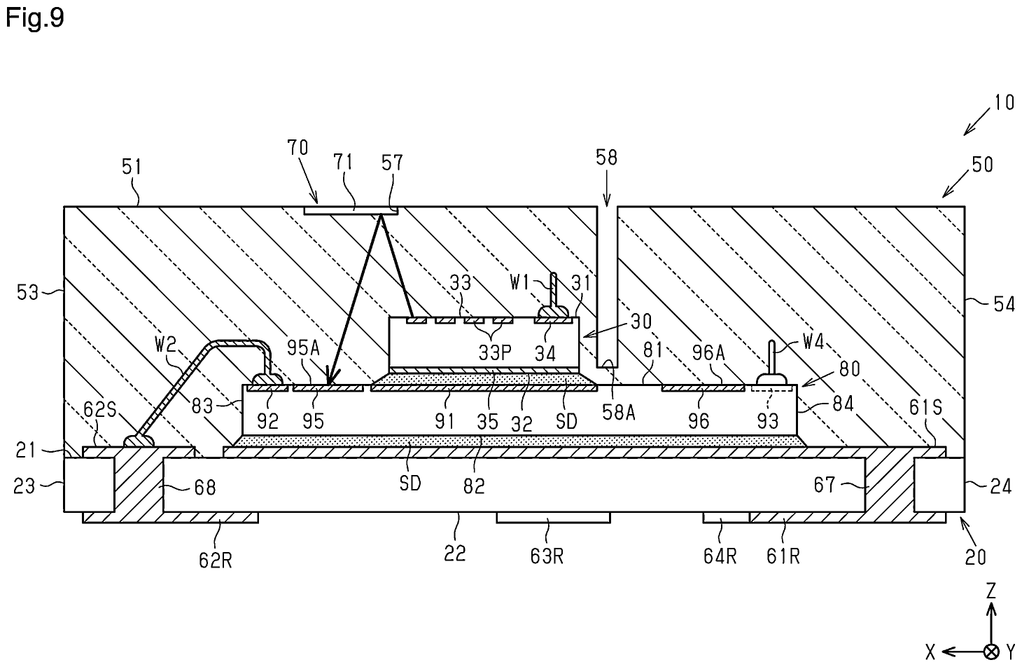

A semiconductor light emitting device 10 according to a fourth embodiment will now be described with reference to FIG. 9. The semiconductor light emitting device 10 of the fourth embodiment is different from the semiconductor light emitting device 10 of the third embodiment mainly in the shape of the sealing member 50. Hereinafter, differences from the semiconductor light emitting device 10 according to the third embodiment will be described in detail, and the same reference numerals are given to components common to the semiconductor light emitting device 10 of the third embodiment, and a detailed description thereof will be omitted. FIG. 9 illustrates a schematic cross-sectional structure of the semiconductor light emitting device 10 cut along the XZ plane.

As illustrated in FIG. 9, the sealing member 50 includes a slit 58. The slit 58 is formed between the surface emitting laser chip 30 and the detection surface 96A in the X direction in the sealing member 50. In the example illustrated in FIG. 9, the slit 58 is arranged closer to the surface emitting laser chip 30 than the detection light receiving element 96 in plan view. That is, in plan view, the distance between the slit 58 and the surface emitting laser chip 30 in the X direction is smaller than the distance between the slit 58 and the detection light receiving element 96 in the X direction. The position of the slit 58 in the X direction can be changed as long as it is between the surface emitting laser chip 30 and the detection light receiving element 96 in the X direction.

The slit 58 extends in the Y direction and the Z direction, with the Z direction representing a depth direction. Therefore, the X direction is the width direction of the slit 58. The slit 58 may be formed, for example, from the third sealing side surface 55 to the fourth sealing side surface 56 (see FIG. 4 for both). That is, the slit 58 may extend through the sealing member 50 in the Y direction. The dimension of the slit 58 in the Y direction can be changed. The dimension of the slit 58 in the Y direction may be smaller than the dimension of the sealing member 50 in the Y direction. That is, the slit 58 may be partially formed in the sealing member 50 in the Y direction. On the other hand, the dimension of the slit 58 in the Y direction may be equal to or larger than the dimension of the surface emitting laser chip 30 in the Y direction.

The slit 58 is formed from the sealing surface 51 of the sealing member 50 toward the light receiving chip 80. A bottom surface 58A of the slit 58 is located closer to the light receiving chip 80 than the first chip front surface 31 of the surface emitting laser chip 30 in the Z direction. In one example, the bottom surface 58A of the slit 58 may be located at the same position as the first chip back surface 32 of the surface emitting laser chip 30 in the Z direction. The position of the bottom surface 58A of the slit 58 in the Z direction can be changed. In one example, the bottom surface 58A of the slit 58 may be located closer to the light receiving chip 80 than the first chip back surface 32 of the surface emitting laser chip 30 in the Z direction. In one example, the bottom surface 58A of the slit 58 may be located closer to the first chip front surface 31 than the first chip back surface 32 of the surface emitting laser chip 30 in the Z direction. That is, the bottom surface 58A of the slit 58 may be located between the first chip front surface 31 and the first chip back surface 32 in the Z direction.

### Advantages

According to the semiconductor light emitting device 10 of the fourth embodiment, the following advantages are obtained.

(4-1) The sealing member 50 includes a slit 58 extending in the Y direction and a Z direction, with the Z direction representing a depth direction. The slit 58 is formed between the surface emitting laser chip 30 and the detection surface 96A of the detection light receiving element 96 in the X direction.

According to this configuration, light leaking from the surface emitting laser chip 30 toward the detection light receiving element 96 is blocked by the slit 58. Therefore, it is possible to prevent the detection light receiving element 96 from receiving the light leaking from the surface emitting laser chip 30.

(4-2) The slit 58 is formed at a position closer to the surface emitting laser chip 30 than the detection light receiving element 96 in plan view.

According to this configuration, the advantage that the light leaking from the surface emitting laser chip 30 toward the detection light receiving element 96 is blocked by the slit 58 is enhanced. Therefore, it is possible to further prevent the detection light receiving element 96 from receiving the light leaking from the surface emitting laser chip 30.

### Fifth Embodiment

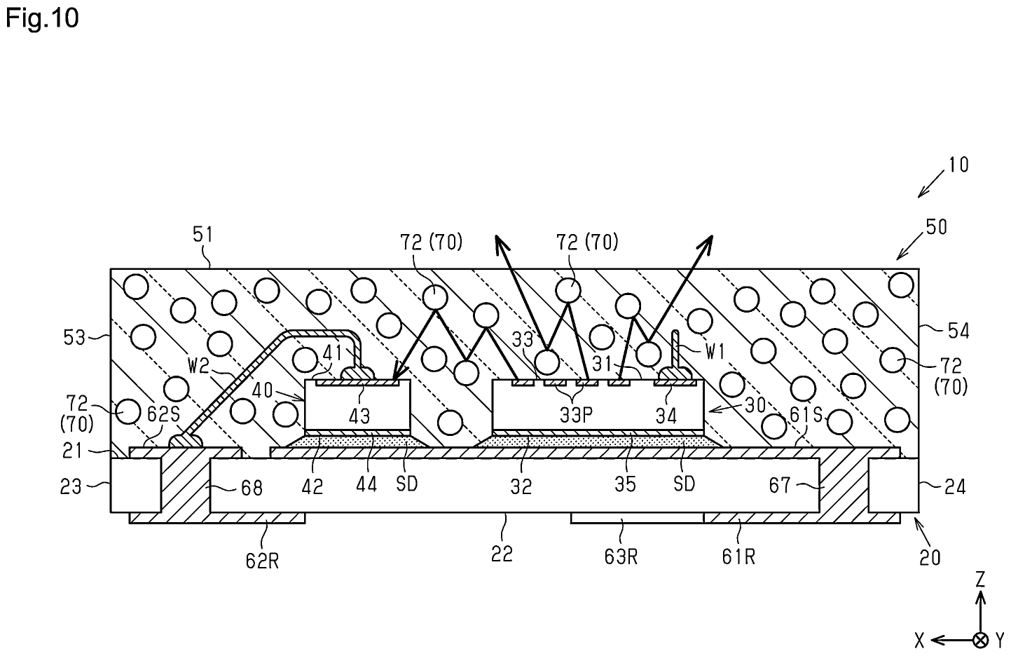

A semiconductor light emitting device 10 according to a fifth embodiment will now be described with reference to FIG. 10. The semiconductor light emitting device 10 of the fifth embodiment is different from the semiconductor light emitting device 10 of the first embodiment mainly in the configuration of the reflecting portion 70. Hereinafter, differences from the semiconductor light emitting device 10 according to the first embodiment will be described in detail, and the same reference numerals are given to components common to the semiconductor light emitting device 10 of the first embodiment, and a detailed description thereof will be omitted. FIG. 10 illustrates a schematic cross-sectional structure of the semiconductor light emitting device 10 cut along the XZ plane.

As illustrated in FIG. 10, the sealing member 50 includes a diffusing material 72 that diffuses light as the reflecting portion 70. The diffusing material 72 diffuses light inside the sealing member 50 by reflecting (scattering) light at an interface between the resin inside the sealing member 50 and the diffusing material 72. As a result, the light receiving chip 40 receives a part of the laser light diffused by the diffusing material 72 inside the sealing member 50 among the laser light emitted from the surface emitting laser chip 30. In addition, the diffusing material 72 plays a role of diffusing the laser light emitted from the surface emitting laser chip 30 inside the sealing member 50 to widen the directional angle of the laser light emitted from the sealing member 50.

The material of the diffusing material 72 is not particularly limited, but for example, silica or another glass material can be used. In one example, a spherical silica filler is used as the diffusing material 72. The particle size of the diffusing material 72 is not particularly limited, but for example, a particle size having a sufficiently small size in relation to the wavelength of the laser light emitted from the surface emitting laser chip 30 is selected so that scattering predominantly occurs.

The diffusing material 72 is dispersed as fine particles in the sealing member 50. The diffusing material 72 is mixed with the sealing member 50 at a predetermined mixing ratio. In one example, the diffusing material 72 is uniformly dispersed in the sealing member 50. The mixing ratio of the diffusing material 72 to the resin of the sealing member 50 is not particularly limited, and may be more than 0% and less than 100%. As the mixing ratio of the diffusing material 72 is increased, the light receiving chip 40 more readily receives scattered light, and the directional angle of the laser light of the surface emitting laser chip 30 is widened. In addition, by limiting the upper limit of the mixing ratio of the diffusing material 72 to a predetermined value, it is possible to prevent a large decrease in the output and radiation intensity of the laser light of the semiconductor light emitting device 10.

In one example, as the diffusing material 72, for example, a material having a thermal expansion coefficient smaller than that of the resin of the sealing member 50 is selected. In this configuration, the thermal stress generated in the sealing member 50 by the diffusing material 72 is reduced as compared with the case in which the sealing member 50 is made only of a resin. Accordingly, it is possible to prevent disconnection of the wires W1 and W2 due to thermal stress of the sealing member 50.

### Advantages

According to the semiconductor light emitting device 10 of the fifth embodiment, the following advantages are obtained.

(5-1) The reflecting portion 70 includes multiple diffusing materials 72 that are provided in the sealing member 50 and diffuse the laser light from the surface emitting laser chip 30. According to this configuration, the laser light from the surface emitting laser chip 30 is diffused by the diffusing materials 72, so that a part of the laser light is diffused toward the light receiving chip 40. Therefore, the light receiving chip 40 readily receives a part of the laser light from the surface emitting laser chip 30.

### Sixth Embodiment

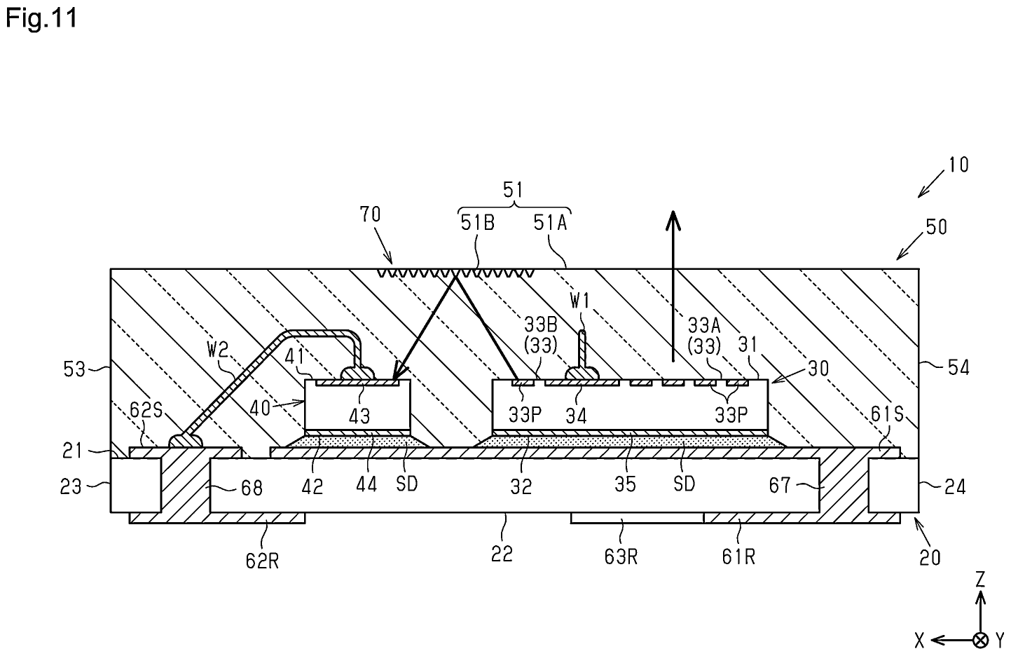

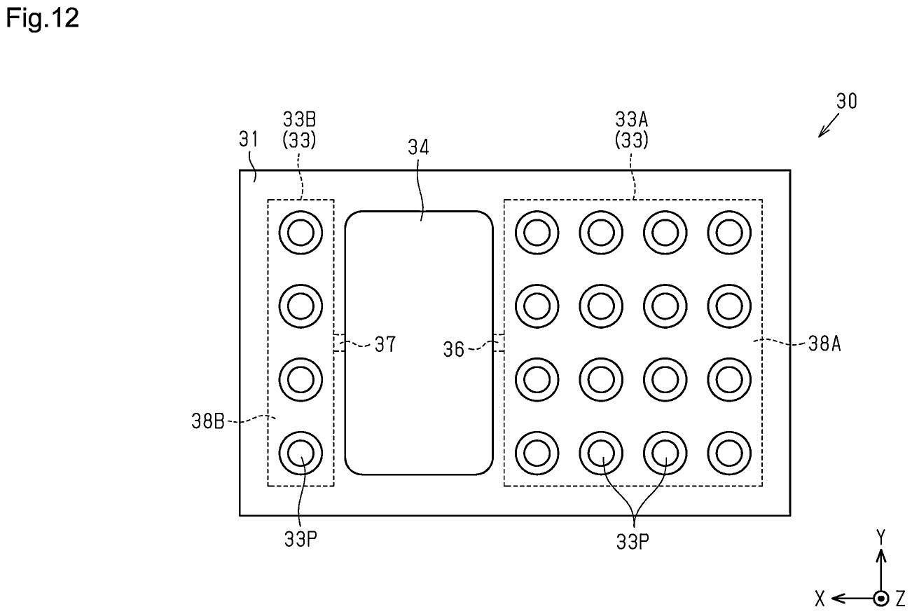

A semiconductor light emitting device 10 according to a sixth embodiment will now be described with reference to FIGS. 11 and 12. The semiconductor light emitting device 10 of the sixth embodiment is different from the semiconductor light emitting device 10 of the first embodiment mainly in the configuration of the surface emitting laser chip 30. Hereinafter, differences from the semiconductor light emitting device 10 according to the first embodiment will be described in detail, and the same reference numerals are given to components common to the semiconductor light emitting device 10 of the first embodiment, and a detailed description thereof will be omitted. FIG. 11 illustrates a schematic cross-sectional structure of the semiconductor light emitting device 10 cut along the XZ plane. FIG. 12 illustrates a schematic planar structure of the surface emitting laser chip 30.

As illustrated in FIGS. 11 and 12, the surface emitting laser chip 30 includes a first light emitting surface 33A and a second light emitting surface 33B as the light emitting surface 33. The first light emitting surface 33A and the second light emitting surface 33B are formed on the first chip front surface 31. The first light emitting surface 33A and the second light emitting surface 33B are formed at different positions in plan view. In the example illustrated in FIG. 12, the first light emitting surface 33A and the second light emitting surface 33B are formed to be separated from each other in the X direction.

The first light emitting surface 33A is, for example, a light emitting surface for emitting laser light toward the object DT (see FIG. 8). As illustrated in FIG. 12, the first light emitting surface 33A is formed in a shape in which the X direction is the transverse direction and the Y direction is the longitudinal direction in plan view. In one example, the first light emitting surface 33A in a plan view has a rectangular shape. The first light emitting surface 33A includes multiple light emitting units 33P. The light emitting units 33P are arranged to be separated from each other in the X direction and the Y direction in plan view. The shape of the first light emitting surface 33A in plan view can be changed.

The region of the broken line frame defining the first light emitting surface 33A is the same as an outer frame of a first light emitting electrode 38A electrically connected to each light emitting unit 33P. That is, in plan view, a region surrounded by the outer frame of the first light emitting electrode 38A is the first light emitting surface 33A.

The second light emitting surface 33B is, for example, a light emitting surface for emitting laser light toward the reflecting portion 70. The second light emitting surface 33B is formed in a shape in which the X direction is the transverse direction and the Y direction is the longitudinal direction in plan view. In one example, the second light emitting surface 33B in plan view has a rectangular shape. The dimension of the second light emitting surface 33B in the Y direction is, for example, equal to the dimension of the first light emitting surface 33A in the Y direction. The dimension of the second light emitting surface 33B in the X direction is smaller than, for example, the dimension of the first light emitting surface 33A in the X direction. Therefore, the area of the second light emitting surface 33B is smaller than the area of the first light emitting surface 33A. The shape of the second light emitting surface 33B in plan view can be changed.

The second light emitting surface 33B includes multiple light emitting units 33P. Since the area of the second light emitting surface 33B is smaller than the area of the first light emitting surface 33A, the number of the light emitting units 33P on the second light emitting surface 33B is smaller than the number of the light emitting units 33P on the first light emitting surface 33A. The light emitting units 33P on the second light emitting surface 33B are arranged at the same position in the X direction and to be separated from each other in the Y direction.

The region of the broken line frame defining the second light emitting surface 33B is the same as an outer frame of a second light emitting electrode 38B electrically connected to each light emitting unit 33P. That is, in plan view, a region surrounded by the outer frame of the second light emitting electrode 38B is defined as the second light emitting surface 33B.

The surface emitting laser chip 30 includes a front electrode 34 formed between the first light emitting surface 33A and the second light emitting surface 33B in the X direction. Since the area of the first light emitting surface 33A is larger than the area of the second light emitting surface 33B, the front electrode 34 is formed at an offset position relative to the center of the surface emitting laser chip 30 in the X direction. The front electrode 34 is an example of an electrode of the surface emitting laser chip 30.

The front electrode 34 is electrically connected to the light emitting units 33P on the first light emitting surface 33A. The front electrode 34 is electrically connected to the light emitting units 33P on the second light emitting surface 33B. More specifically, the surface emitting laser chip 30 includes a first connecting portion 36 that electrically connects the light emitting units 33P on the first light emitting surface 33A and the front electrode 34, and a second connecting portion 37 that electrically connects the light emitting units 33P on the second light emitting surface 33B and the front electrode 34. Therefore, the light emitting units 33P on the first light emitting surface 33A and the light emitting units 33P on the second light emitting surface 33B are configured to simultaneously emit laser light.

The first connecting portion 36 is connected to the first light emitting electrode 38A constituting the first light emitting surface 33A. Thus, the first connecting portion 36 is electrically connected to the light emitting units 33P on the first light emitting surface 33A via the first light emitting electrode 38A. The second connecting portion 37 is connected to the second light emitting electrode 38B constituting the second light emitting surface 33B. Thus, the second connecting portion 37 is electrically connected to the light emitting units 33P on the second light emitting surface 33B via the second light emitting electrode 38B. The first connecting portion 36 and the second connecting portion 37 may include, for example, a wiring layer and a via.

As illustrated in FIG. 11, similarly to the first embodiment, the light receiving chip 40 is arranged closer to the first substrate side surface 23 than the surface emitting laser chip 30. The light receiving chip 40 is arranged on the side opposite to the first light emitting surface 33A with respect to the second light emitting surface 33B. That is, the light receiving chip 40 is arranged closer to the second light emitting surface 33B than the first light emitting surface 33A in the X direction.

The reflecting portion 70 is formed between the surface emitting laser chip 30 and the light receiving chip 40 in the X direction in plan view. In one example, the reflecting portion 70 includes a portion overlapping with the light receiving chip 40 in plan view. In the example illustrated in FIG. 11, the reflecting portion 70 includes a portion overlapping with an end portion closer to the surface emitting laser chip 30 among the opposite end portions of the light receiving chip 40 in the X direction in plan view. Furthermore, in one example, the reflecting portion 70 includes a portion overlapping with the surface emitting laser chip 30 in plan view. More specifically, the reflecting portion 70 is formed at a position overlapping with the second light emitting surface 33B in plan view. The reflecting portion 70 may be formed to face the entire second light emitting surface 33B in the Z direction. The reflecting portion 70 may include a portion overlapping with the front electrode 34 in plan view. On the other hand, the reflecting portion 70 is formed to be located closer to the light receiving chip 40 than the first light emitting surface 33A in plan view. The configuration of the reflecting portion 70 and the configuration of the sealing member 50 related to the reflecting portion 70 are similar to those of the second embodiment.

### Operation

Operation of the sixth embodiment will now be described.

When APC driving is performed on the semiconductor light emitting device 10, it is necessary to reflect a part of the laser light of the surface emitting laser chip 30 toward the light receiving chip 40, and thus the semiconductor light emitting device 10 includes the reflecting portion 70. For example, the reflecting portion 70 may be provided to face a part of the light emitting surface 33 of the surface emitting laser chip 30. In this case, if the reflecting portion 70 faces the light emitting surface 33 more than necessary due to positional deviation of the reflecting portion 70 or the like, the laser light emitted from the surface emitting laser chip 30 is blocked more than necessary by the reflecting portion 70, so that the output of the laser light emitted from the semiconductor light emitting device 10 decreases. That is, for example, when the reflecting portion 70 covers the first light emitting surface 33A, the laser light emitted from the semiconductor light emitting device 10 is blocked by the reflecting portion 70, so that the output of the laser light emitted from the semiconductor light emitting device 10 decreases.

In the sixth embodiment, the surface emitting laser chip 30 includes the front electrode 34 provided between the first light emitting surface 33A and the second light emitting surface 33B in the X direction. As a result, for example, even if the position of the reflecting portion 70 is deviated in the X direction when the reflecting portion 70 faces the second light emitting surface 33B, the reflecting portion 70 covers the front electrode 34 and prevents the first light emitting surface 33A from being covered. That is, the region where the front electrode 34 is formed is a region where the positional deviation of the reflecting portion 70 in the X direction is allowed. Therefore, it is possible to prevent the laser light from the surface emitting laser chip 30 from being blocked more than necessary by the reflecting portion 70. Then, it is possible to limit a decrease in output due to the positional deviation of the reflecting portion 70.

### Advantages

According to the semiconductor light emitting device of the sixth embodiment, the following advantages are obtained.

(6-1) The surface emitting laser chip 30 includes the first chip front surface 31 and the first chip back surface 32 facing opposite sides, the first light emitting surface 33A and the second light emitting surface 33B formed on the first chip front surface 31 and configured to emit laser light, and the front electrode 34 formed on the first chip front surface 31 and formed at a position separated from each of the first light emitting surface 33A and the second light emitting surface 33B. In plan view, the first light emitting surface 33A and the second light emitting surface 33B are arranged to be separated from each other in a X direction. The front electrode 34 is arranged between the first light emitting surface 33A and the second light emitting surface 33B in the X direction.

According to this configuration, for example, in a case in which the reflecting portion 70 is provided to face a part of the second light emitting surface 33B of the surface emitting laser chip 30, even if the position of the reflecting portion 70 is deviated in the X direction, the reflecting portion 70 is prevented from covering the first light emitting surface 33A. Therefore, it is possible to prevent the laser light from the surface emitting laser chip 30 from being blocked by the reflecting portion 70 more than necessary. Then, it is possible to limit a decrease in output due to the positional deviation of the reflecting portion 70.

(6-2) In plan view, the area of the second light emitting surface 33B is smaller than the area of the first light emitting surface 33A.

According to this configuration, the output of the laser light from the second light emitting surface 33B is smaller than the output of the laser light from the first light emitting surface 33A. For this reason, for example, the laser light from the second light emitting surface 33B can be employed in a configuration in which an output of laser light is small such that the laser light is reflected by the reflecting portion 70 and received by the light receiving chip 40. In addition, the laser light from the first light emitting surface 33A can be employed in a configuration in which an output of laser light is large such that the laser light is emitted from the semiconductor light emitting device 10.

(6-3) Each of the first light emitting surface 33A and the second light emitting surface 33B includes the light emitting unit 33P that emits laser light. The number of the light emitting units 33P on the second light emitting surface 33B is smaller than the number of the light emitting units 33P on the first light emitting surface 33A.

According to this configuration, the output of the laser light from the second light emitting surface 33B is smaller than the output of the laser light from the first light emitting surface 33A. For this reason, for example, the laser light from the second light emitting surface 33B can be employed in a configuration in which an output of laser light is small such that the laser light is reflected by the reflecting portion 70 and received by the light receiving chip 40. In addition, the laser light from the first light emitting surface 33A can be employed in a configuration in which an output of laser light is large such that the laser light is emitted from the semiconductor light emitting device 10.

(6-4) The front electrode 34 is electrically connected to both the light emitting unit 33P on the first light emitting surface 33A and the light emitting unit 33P on the second light emitting surface 33B.

According to this configuration, the light emitting unit 33P on the first light emitting surface 33A and the light emitting unit 33P on the second light emitting surface 33B simultaneously emit laser light. In addition, since the front electrode 34 is a common electrode for the light emitting unit 33P on the first light emitting surface 33A and the light emitting unit 33P on the second light emitting surface 33B, the configuration of the surface emitting laser chip 30 is simplified.

### Seventh Embodiment

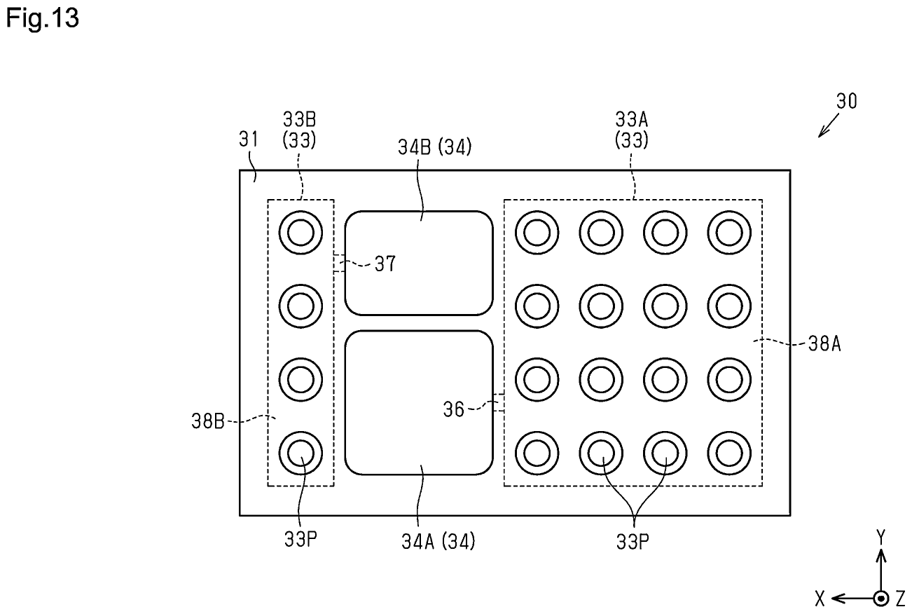

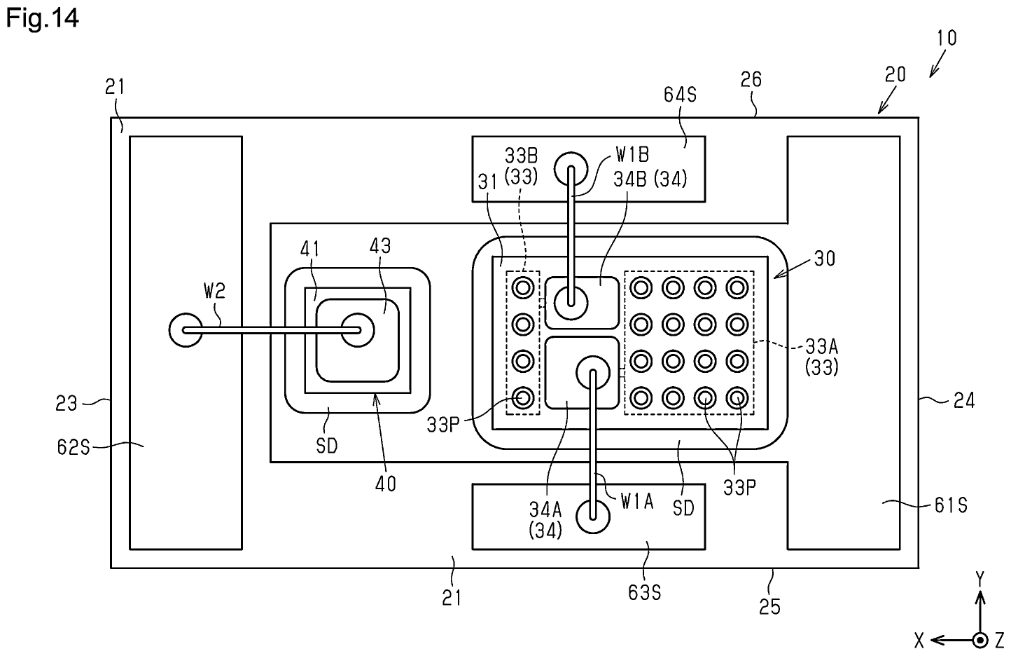

A semiconductor light emitting device 10 according to a seventh embodiment will now be described with reference to FIGS. 13 and 14. The semiconductor light emitting device 10 of the seventh embodiment is different from the semiconductor light emitting device 10 of the sixth embodiment mainly in the configuration of the surface emitting laser chip 30. Hereinafter, differences from the semiconductor light emitting device 10 according to the sixth embodiment will be described in detail, and the same reference numerals are given to components common to the semiconductor light emitting device 10 of the sixth embodiment, and a detailed description thereof will be omitted. FIG. 13 illustrates a schematic planar structure of a surface emitting laser chip 30 of the seventh embodiment. FIG. 14 illustrates a schematic planar structure of the semiconductor light emitting device 10 including the surface emitting laser chip 30 of FIG. 13. In FIG. 14, the sealing member 50 and the reflecting portion 70 are omitted for easy understanding of the drawings.

As illustrated in FIG. 13, the surface emitting laser chip 30 of the seventh embodiment is different from the surface emitting laser chip 30 of the sixth embodiment mainly in the configuration of the front electrode 34. More specifically, the front electrode 34 includes a first electrode 34A and a second electrode 34B arranged to be separated from each other. In the example illustrated in FIG. 13, the first electrode 34A and the second electrode 34B are arranged at the same position in the X direction and to be separated from each other in the Y direction. The area of the first electrode 34A in plan view is larger than the area of the second electrode 34B in plan view.

The first electrode 34A is electrically connected to the light emitting units 33P on the first light emitting surface 33A. The second electrode 34B is electrically connected to the light emitting units 33P on the second light emitting surface 33B. More specifically, the surface emitting laser chip 30 includes a first connecting portion 36 that electrically connects the first electrode 34A and the light emitting units 33P on the first light emitting surface 33A, and a second connecting portion 37 that electrically connects the second electrode 34B and the light emitting units 33P on the second light emitting surface 33B. Therefore, the light emitting units 33P on the first light emitting surface 33A and the light emitting units 33P on the second light emitting surface 33B are configured to individually emit laser light. The configurations of the first connecting portion 36 and the second connecting portion 37 may be, for example, the same as those of the sixth embodiment.

As illustrated in FIG. 14, the semiconductor light emitting device 10 includes a first front electrode 61S, a second front electrode 62S, a third front electrode 63S, and a fourth front electrode 64S formed on the substrate front surface 21. The arrangement, shape, and size of the first front electrode 61S and the second front electrode 62S are the same as those in the first embodiment.

The third front electrode 63S and the fourth front electrode 64S are dispersedly arranged on the opposite sides of the surface emitting laser chip 30 in the Y direction in plan view. The third front electrode 63S and the fourth front electrode 64S are arranged at the same position in the X direction. The third front electrode 63S is arranged closer to the third substrate side surface 25 than the surface emitting laser chip 30. The fourth front electrode 64S is arranged closer to the fourth substrate side surface 26 than the surface emitting laser chip 30. The third front electrode 63S and the fourth front electrode 64S are arranged closer to the second substrate side surface 24 than the light receiving chip 40. The shape of the third front electrode 63S and the fourth front electrode 64S in plan view is a rectangular shape in which the X direction is the longitudinal direction and the Y direction is the transverse direction.

The first electrode 34A and the third front electrode 63S are electrically connected by a wire W1A. The second electrode 34B and the fourth front electrode 64S are electrically connected by a wire W1B. The wires W1A and W1B are formed of, for example, the same material as the wire W1 (see FIG. 11). As described above, by electrically connecting the first electrode 34A and the second electrode 34B to the individual front electrodes (the third front electrode 63S and the fourth front electrode 64S), the light emitting units 33P on the first light emitting surface 33A and the light emitting units 33P on the second light emitting surface 33B are configured to individually emit laser light.

In the example illustrated in FIG. 14, the numbers of wires W1A and W1B are one, but the numbers of wires W1A and W1B can be changed. In one example, the number of the wires W1A may be two. That is, the number of the wires W1A may be larger than the number of the wires W1B. The number of the wires W1A and W1B may be set according to, for example, the number of the light emitting units 33P on the first light emitting surface 33A and the number of the light emitting units 33P on the second light emitting surface 33B.

Although not illustrated, the semiconductor light emitting device 10 includes a first back electrode 61R, a second back electrode 62R, a third back electrode, and a fourth back electrode formed on the substrate back surface 22, and a first via 67, a second via 68, a third via, and a fourth via formed on the substrate 20. The arrangement, shape, and size of the first front electrode 61S, the second front electrode 62S, the first via 67, and the second via 68 are the same as those in the first embodiment.

The third back electrode is formed at a position closer to the third substrate side surface 25 than the center of the substrate back surface 22 in the Y direction. In plan view, the third back electrode includes a portion overlapping with the third front electrode 63S (see FIG. 13).

The fourth back electrode is formed at a position closer to the fourth substrate side surface 26 than the center of the substrate back surface 22 in the Y direction. In plan view, the fourth back electrode includes a portion overlapping with the fourth front electrode 64S (see FIG. 14).

The third via electrically connects the third front electrode 63S and the third back electrode. The fourth via electrically connects the fourth front electrode 64S and the fourth back electrode. Each of the third via and the fourth via extends through the substrate 20 in the Z direction. Multiple first vias 67, multiple second vias 68, multiple third vias, and multiple fourth vias may be provided.

Although not illustrated, the semiconductor light emitting device 10 includes the reflecting portion 70 (see FIG. 3). The positional relationship between the reflecting portion 70 and the surface emitting laser chip 30 and the light receiving chip 40 is similar to that of the first embodiment. The configuration of the reflecting portion 70 and the configuration of the sealing member 50 related to the reflecting portion 70 are similar to those of the first embodiment.

### Advantages

According to the semiconductor light emitting device of the seventh embodiment, the following advantages are obtained.

(7-1) The front electrode 34 includes a first electrode 34A and a second electrode 34B arranged to be separated from each other. The first electrode 34A is electrically connected to the light emitting unit 33P on the first light emitting surface 33A. The second electrode 34B is electrically connected to the light emitting unit 33P on the second light emitting surface 33B.

According to this configuration, by using the first electrode 34A and the second electrode 34B, the laser light is individually emitted in the light emitting unit 33P on the first light emitting surface 33A and the light emitting unit 33P on the second light emitting surface 33B.

### Eighth Embodiment

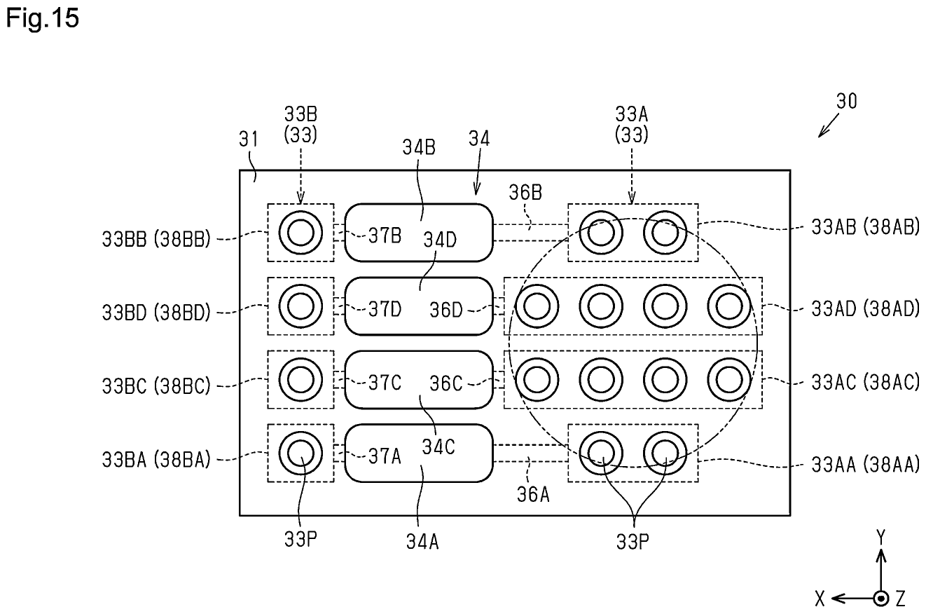

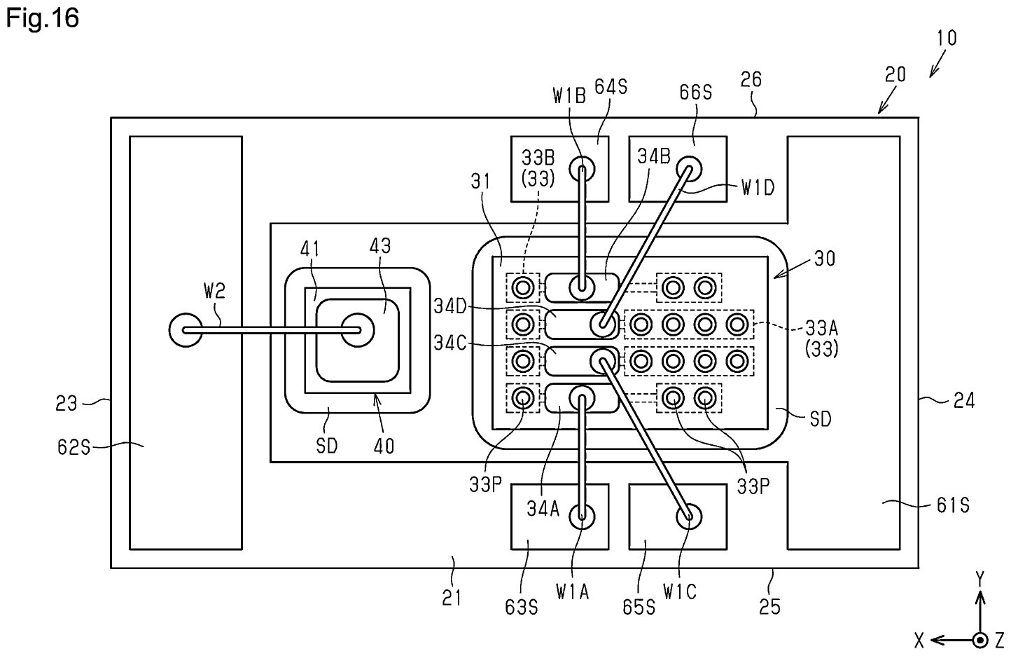

A semiconductor light emitting device 10 according to an eighth embodiment will now be described with reference to FIGS. 15 and 16. The semiconductor light emitting device 10 of the eighth embodiment is different from the semiconductor light emitting device 10 of the sixth embodiment mainly in the configuration of the surface emitting laser chip 30. Hereinafter, differences from the semiconductor light emitting device 10 according to the sixth embodiment will be described in detail, and the same reference numerals are given to components common to the semiconductor light emitting device 10 of the sixth embodiment, and a detailed description thereof will be omitted. FIG. 15 illustrates a schematic planar structure of the surface emitting laser chip 30 of the eighth embodiment. FIG. 16 illustrates a schematic planar structure of the semiconductor light emitting device 10 including the surface emitting laser chip 30 of FIG. 15. In FIG. 16, the sealing member 50 and the reflecting portion 70 are omitted for easy understanding of the drawings.

As illustrated in FIG. 15, the surface emitting laser chip 30 of the eighth embodiment is different from the surface emitting laser chip 30 of the sixth embodiment mainly in the configurations of the first light emitting surface 33A, the second light emitting surface 33B, and the front electrode 34.

The first light emitting surface 33A includes a first main light emitting region 33AA, a second main light emitting region 33AB, a third main light emitting region 33AC, and a fourth main light emitting region 33AD as four light emitting regions. The first main light emitting region 33AA, the second main light emitting region 33AB, the third main light emitting region 33AC, and the fourth main light emitting region 33AD are arranged to be separated from each other in the Y direction. In the example of FIG. 15, centers of the first main light emitting region 33AA, the second main light emitting region 33AB, the third main light emitting region 33AC, and the fourth main light emitting region 33AD in the X direction are at the same position in the X direction.

The first main light emitting region 33AA and the second main light emitting region 33AB form end portions of the first light emitting surface 33A in the Y direction. The third main light emitting region 33AC and the fourth main light emitting region 33AD are arranged between the first main light emitting region 33AA and the second main light emitting region 33AB in the Y direction. The third main light emitting region 33AC is arranged closer to the first main light emitting region 33AA than the second main light emitting region 33AB. The fourth main light emitting region 33AD is arranged closer to the second main light emitting region 33AB than the first main light emitting region 33AA. That is, the third main light emitting region 33AC is arranged between the first main light emitting region 33AA and the fourth main light emitting region 33AD in the Y direction. The fourth main light emitting region 33AD is arranged between the second main light emitting region 33AB and the third main light emitting region 33AC in the Y direction.

Each of the first to fourth main light emitting regions 33AA to 33AD is formed in a rectangular shape in which the X direction is the longitudinal direction and the Y direction is the transverse direction in plan view. The lengths of the first main light emitting region 33AA and the second main light emitting region 33AB in the X direction are shorter than the lengths of the third main light emitting region 33AC and the fourth main light emitting region 33AD in the X direction. The lengths of the first main light emitting region 33AA and the second main light emitting region 33AB in the Y direction are equal to the lengths of the third main light emitting region 33AC and the fourth main light emitting region 33AD in the Y direction. That is, the areas of the first main light emitting region 33AA and the second main light emitting region 33AB in plan view are smaller than the areas of the third main light emitting region 33AC and the fourth main light emitting region 33AD in plan view.

Each of the first to fourth main light emitting regions 33AA to 33AD includes multiple light emitting units 33P. The light emitting units 33P in each of the first to fourth main light emitting regions 33AA to 33AD are arranged at the same position in the Y direction and to be separated from each other in the X direction. That is, the light emitting units 33P in each of the first to fourth main light emitting regions 33AA to 33AD are arranged in a line in the X direction.

In one example, the number of the light emitting units 33P in the first main light emitting region 33AA and the second main light emitting region 33AB is smaller than the number of the light emitting units 33P in the third main light emitting region 33AC and the fourth main light emitting region 33AD. In the example illustrated in FIG. 15, the number of the light emitting units 33P in the first main light emitting region 33AA is the same as the number of the light emitting units 33P in the second main light emitting region 33AB. The number of the light emitting units 33P in the third main light emitting region 33AC is the same as the number of the light emitting units 33P in the fourth main light emitting region 33AD. As described above, the first light emitting surface 33A has a circular shape (two-dot chain line in FIG. 15) in plan view. In other words, the light emitting units 33P arranged in the outer peripheral portion among the light emitting units 33P in the first to fourth main light emitting regions 33AA to 33AD are arranged to have a circular shape in plan view. Therefore, the light emitting units 33P in the first to fourth main light emitting regions 33AA to 33AD are configured to emit circular laser light in plan view.

The regions of the broken line frames defining the first to fourth main light emitting regions 33AA to 33AD are the same as outer frames of the first to fourth light emitting electrodes 38AA to 38AD electrically connected to each light emitting unit 33P. That is, in plan view, the region surrounded by the outer frame of the first light emitting electrode 38AA is referred to as a first main light emitting region 33AA, the region surrounded by the outer frame of the second light emitting electrode 38AB is referred to as a second main light emitting region 33AB, the region surrounded by the outer frame of the third light emitting electrode 38AC is referred to as a third main light emitting region 33AC, and the region surrounded by the outer frame of the fourth light emitting electrode 38AD is referred to as a fourth main light emitting region 33AD.

The second light emitting surface 33B includes a first light emitting region 33BA, a second light emitting region 33BB, a third light emitting region 33BC, and a fourth light emitting region 33BD as four light emitting regions. The first light emitting region 33BA, the second light emitting region 33BB, the third light emitting region 33BC, and the fourth light emitting region 33BD are arranged at the same position in the X direction and to be separated from each other in the Y direction.

The first light emitting region 33BA and the second light emitting region 33BB form end portions of the second light emitting surface 33B in the Y direction. The third light emitting region 33BC and the fourth light emitting region 33BD are arranged between the first light emitting region 33BA and the second light emitting region 33BB in the Y direction. The third light emitting region 33BC is arranged closer to the first light emitting region 33BA than the second light emitting region 33BB. The fourth light emitting region 33BD is arranged closer to the second light emitting region 33BB than the first light emitting region 33BA. The third light emitting region 33BC is arranged between the first light emitting region 33BA and the fourth light emitting region 33BD in the Y direction. The fourth light emitting region 33BD is arranged between the second light emitting region 33BB and the third light emitting region 33BC in the Y direction.

The first light emitting region 33BA is arranged at the same position as the first main light emitting region 33AA in the Y direction. In plan view, the area of the first light emitting region 33BA is smaller than the area of the first main light emitting region 33AA. More specifically, the length of the first light emitting region 33BA in the X direction is shorter than the length of the first main light emitting region 33AA in the X direction. The length of the first light emitting region 33BA in the Y direction is equal to the length of the first main light emitting region 33AA in the Y direction.

The first light emitting region 33BA includes a light emitting unit 33P. The number of the light emitting units 33P in the first light emitting region 33BA is smaller than the number of the light emitting units 33P in the first main light emitting region 33AA. In the example illustrated in FIG. 15, the first light emitting region 33BA includes one light emitting unit 33P.

The second light emitting region 33BB is arranged at the same position as the second main light emitting region 33AB in the Y direction. In plan view, the area of the second light emitting region 33BB is smaller than the area of the second main light emitting region 33AB. More specifically, the length of the second light emitting region 33BB in the X direction is shorter than the length of the second main light emitting region 33AB in the X direction. The length of the second light emitting region 33BB in the Y direction is equal to the length of the second main light emitting region 33AB in the Y direction.

The second light emitting region 33BB includes a light emitting unit 33P. The number of the light emitting units 33P in the second light emitting region 33BB is smaller than the number of the light emitting units 33P in the second main light emitting region 33AB. In the example illustrated in FIG. 15, the second light emitting region 33BB includes one light emitting unit 33P.

The third light emitting region 33BC is arranged at the same position as the third main light emitting region 33AC in the Y direction. In plan view, the area of the third light emitting region 33BC is smaller than the area of the third main light emitting region 33AC. More specifically, the length of the third light emitting region 33BC in the X direction is shorter than the length of the third main light emitting region 33AC in the X direction. The length of the third light emitting region 33BC in the Y direction is equal to the length of the third main light emitting region 33AC in the Y direction.

The third light emitting region 33BC includes a light emitting unit 33P. The number of the light emitting units 33P in the third light emitting region 33BC is smaller than the number of the light emitting units 33P in the third main light emitting region 33AC. In the example illustrated in FIG. 15, the third light emitting region 33BC includes one light emitting unit 33P.

The fourth light emitting region 33BD is arranged at the same position as the fourth main light emitting region 33AD in the Y direction. In plan view, the area of the fourth light emitting region 33BD is smaller than the area of the fourth main light emitting region 33AD. More specifically, the length of the fourth light emitting region 33BD in the X direction is shorter than the length of the fourth main light emitting region 33AD in the X direction. The length of the fourth light emitting region 33BD in the Y direction is equal to the length of the fourth main light emitting region 33AD in the Y direction.

The fourth light emitting region 33BD includes a light emitting unit 33P. The number of the light emitting units 33P in the fourth light emitting region 33BD is smaller than the number of the light emitting units 33P in the fourth main light emitting region 33AD. In the example illustrated in FIG. 15, the fourth light emitting region 33BD includes one light emitting unit 33P.

In this manner, the numbers of light emitting units 33P in the first to fourth light emitting regions 33BA to 33BD are equal to each other. In addition, the areas of the first to fourth light emitting regions 33BA to 33BD in plan view are equal to each other. The number of the light emitting units 33P in the first to fourth light emitting regions 33BA to 33BD can be individually changed. In addition, the areas of the first to fourth light emitting regions 33BA to 33BD in plan view can be individually changed according to the numbers of light emitting units 33P in the first to fourth light emitting regions 33BA to 33BD.

The regions of the broken line frames defining the first to fourth light emitting regions 33BA to 33BD are the same as outer frames of the first to fourth light emitting electrodes 38BA to 38BD electrically connected to each light emitting unit 33P. That is, in plan view, the region surrounded by the outer frame of the first light emitting electrode 38BA is referred to as the first light emitting region 33BA, the region surrounded by the outer frame of the second light emitting electrode 38BB is referred to as a second light emitting region 33BB, the region surrounded by the outer frame of the third light emitting electrode 38BC is referred to as a third light emitting region 33BC, and the region surrounded by the outer frame of the fourth light emitting electrode 38BD is referred to as a fourth light emitting region 33BD.

The front electrode 34 includes a first electrode 34A, a second electrode 34B, a third electrode 34C, and a fourth electrode 34D as four electrodes. The first electrode 34A, the second electrode 34B, the third electrode 34C, and the fourth electrode 34D are arranged at the same position in the X direction and to be separated from each other in the Y direction. In plan view, the first to fourth electrodes 34A to 34D are formed in a rectangular shape in which the X direction is the longitudinal direction and the Y direction is the transverse direction.

The first electrode 34A is arranged at the same position as the first main light emitting region 33AA and the first light emitting region 33BA in the Y direction. The first electrode 34A is electrically connected to the light emitting unit 33P in the first light emitting region 33BA and the light emitting units 33P in the first main light emitting region 33AA. More specifically, the surface emitting laser chip 30 includes a first connecting portion 36A that electrically connects the first electrode 34A and the light emitting units 33P in the first main light emitting region 33AA, and a second connecting portion 37A that electrically connects the first electrode 34A and the light emitting unit 33P in the first light emitting region 33BA. Therefore, a current is simultaneously supplied to the light emitting units 33P in the first main light emitting region 33AA and the light emitting unit 33P in the first light emitting region 33BA via the first electrode 34A, the first connecting portion 36A, and the second connecting portion 37A. That is, the surface emitting laser chip 30 is configured such that the light emitting units 33P in the first main light emitting region 33AA and the light emitting unit 33P in the first light emitting region 33BA simultaneously emit laser light. The first connecting portion 36A is connected to the first light emitting electrode 38AA constituting the first main light emitting region 33AA. The second connecting portion 37A is connected to the first light emitting electrode 38BA constituting the first light emitting region 33BA.

The second electrode 34B is arranged at the same position as the second main light emitting region 33AB and the second light emitting region 33BB in the Y direction. The second electrode 34B is electrically connected to the light emitting unit 33P in the second light emitting region 33BB and the light emitting units 33P in the second main light emitting region 33AB. More specifically, the surface emitting laser chip 30 includes a first connecting portion 36B that electrically connects the second electrode 34B and the light emitting units 33P in the second main light emitting region 33AB, and a second connecting portion 37B that electrically connects the second electrode 34B and the light emitting unit 33P in the second light emitting region 33BB. Therefore, a current is simultaneously supplied to the light emitting units 33P in the second main light emitting region 33AB and the light emitting unit 33P in the second light emitting region 33BB via the second electrode 34B, the first connecting portion 36B, and the second connecting portion 37B. That is, the surface emitting laser chip 30 is configured such that the light emitting units 33P in the second main light emitting region 33AB and the light emitting unit 33P in the second light emitting region 33BB simultaneously emit laser light. The first connecting portion 36B is connected to the second light emitting electrode 38AB constituting the second main light emitting region 33AB. The second connecting portion 37B is connected to the second light emitting electrode 38BB constituting the second light emitting region 33BB.

The third electrode 34C is arranged at the same position as the third main light emitting region 33AC and the third light emitting region 33BC in the Y direction. The third electrode 34C is electrically connected to the light emitting unit 33P in the third light emitting region 33BC and the light emitting units 33P in the third main light emitting region 33AC. More specifically, the surface emitting laser chip 30 includes a first connecting portion 36C that electrically connects the third electrode 34C and the light emitting units 33P in the third main light emitting region 33AC, and a second connecting portion 37C that electrically connects the third electrode 34C and the light emitting unit 33P in the third light emitting region 33BC. Therefore, a current is simultaneously supplied to the light emitting units 33P in the third main light emitting region 33AC and the light emitting unit 33P in the third light emitting region 33BC via the third electrode 34C, the first connecting portion 36C, and the second connecting portion 37C. That is, the surface emitting laser chip 30 is configured such that the light emitting units 33P in the third main light emitting region 33AC and the light emitting unit 33P in the third light emitting region 33BC simultaneously emit laser light. The first connecting portion 36C is connected to the third light emitting electrode 38AC constituting the third main light emitting region 33AC. The second connecting portion 37C is connected to the third light emitting electrode 38BC constituting the third light emitting region 33BC.

The fourth electrode 34D is arranged at the same position as the fourth main light emitting region 33AD and the fourth light emitting region 33BD in the Y direction. The fourth electrode 34D is electrically connected to the light emitting unit 33P in the fourth light emitting region 33BD and the light emitting units 33P in the fourth main light emitting region 33AD. More specifically, the surface emitting laser chip 30 includes a first connecting portion 36D that electrically connects the fourth electrode 34D and the light emitting units 33P in the fourth main light emitting region 33AD, and a second connecting portion 37D that electrically connects the fourth electrode 34D and the light emitting unit 33P in the fourth light emitting region 33BD. Therefore, a current is simultaneously supplied to the light emitting units 33P in the fourth main light emitting region 33AD and the light emitting unit 33P in the fourth light emitting region 33BD via the fourth electrode 34D, the first connecting portion 36D, and the second connecting portion 37D. That is, the surface emitting laser chip 30 is configured such that the light emitting units 33P in the fourth main light emitting region 33AD and the light emitting unit 33P in the fourth light emitting region 33BD simultaneously emit laser light. The first connecting portion 36D is connected to the fourth light emitting electrode 38AD constituting the fourth main light emitting region 33AD. The second connecting portion 37D is connected to the fourth light emitting electrode 38BD constituting the fourth light emitting region 33BD. Each of the first connecting portions 36A to 36D and the second connecting portions 37A to 37D includes, for example, a wiring layer and a via.

Each of the distance between the first electrode 34A and the first main light emitting region 33AA in the X direction and the distance between the second electrode 34B and the second main light emitting region 33AB in the X direction is larger than the distance between the third electrode 34C and the third main light emitting region 33AC in the X direction and the distance between the fourth electrode 34D and the fourth main light emitting region 33AD in the X direction.

As illustrated in FIG. 16, the semiconductor light emitting device 10 including the surface emitting laser chip 30 illustrated in FIG. 15 includes a first front electrode 61S, a second front electrode 62S, a third front electrode 63S, a fourth front electrode 64S, a fifth front electrode 65S, and a sixth front electrode 66S formed on the substrate front surface 21. The first front electrode 61S, the second front electrode 62S, the third front electrode 63S, the fourth front electrode 64S, the fifth front electrode 65S, and the sixth front electrode 66S are arranged to be separated from each other. The arrangement, shape, and size of the first front electrode 61S and the second front electrode 62S are the same as those in the first embodiment.

Two of the third to sixth front electrodes 63S to 66S are dispersedly arranged on each side in the Y direction of the surface emitting laser chip 30 in plan view. More specifically, the third front electrode 63S and the fifth front electrode 65S are arranged closer to the third substrate side surface 25 than the surface emitting laser chip 30. The fourth front electrode 64S and the sixth front electrode 66S are arranged closer to the fourth substrate side surface 26 than the surface emitting laser chip 30. The third front electrode 63S and the fifth front electrode 65S are arranged at the same position in the Y direction and to be separated from each other in the X direction. The third front electrode 63S is arranged closer to the first substrate side surface 23 than the fifth front electrode 65S. The fourth front electrode 64S and the sixth front electrode 66S are arranged at the same position in the Y direction and to be separated from each other in the X direction. The fourth front electrode 64S is arranged closer to the first substrate side surface 23 than the sixth front electrode 66S is.

Although not illustrated, the semiconductor light emitting device 10 includes a first back electrode 61R, a second back electrode 62R, a third back electrode, a fourth back electrode, a fifth back electrode, and a sixth back electrode, and a first via 67, a second via 68, a third via, a fourth via, a fifth via, and a sixth via. The arrangement, shape, and size of the first back electrode 61R, the second back electrode 62R, the first via 67, and the second via 68 are the same as those in the first embodiment.

The third to fifth back electrodes are arranged to be separated from both the first back electrode 61R and the second back electrode 62R (see FIG. 11). The third back electrode, the fourth back electrode, and the fifth back electrode are arranged to be separated from each other. The third back electrode includes a portion overlapping with the third front electrode 63S in plan view. The fourth back electrode includes a portion overlapping with the fourth front electrode 64S in plan view. The fifth back electrode includes a portion overlapping with the fifth front electrode 65S in plan view. The sixth back electrode includes a portion overlapping with the sixth front electrode 66S in plan view.

The third back electrode is electrically connected to the third front electrode 63S via the third via. The fourth back electrode is electrically connected to the fourth front electrode 64S via the fourth via. The fifth back electrode is electrically connected to the fifth front electrode 65S via the fifth via. The sixth back electrode is electrically connected to the sixth front electrode 66S via the sixth via.

Each of the third to sixth vias extends through the substrate 20 in the Z direction. The third via is in contact with both the third back electrode and the third front electrode 63S. The fourth via is in contact with both the fourth back electrode and the fourth front electrode 64S. The fifth via is in contact with both the fifth back electrode and the fifth front electrode 65S. The sixth via is in contact with both the sixth back electrode and the sixth front electrode 66S.

The first electrode 34A and the third front electrode 63S are electrically connected by a wire W1A. The second electrode 34B and the fourth front electrode 64S are electrically connected by a wire W1B. The third electrode 34C and the fifth front electrode 65S are electrically connected by a wire W1C. The fourth electrode 34D and the sixth front electrode 66S are electrically connected by a wire W1D. The wires W1A to W1D are formed of, for example, the same material as the wire W1 (see FIG. 11).

As described above, by electrically connecting the first to fourth electrodes 34A to 34D to the individual front electrodes (the third to sixth front electrodes 63S to 66S), it is possible to achieve such configuration that a set of the light emitting units 33P in the first main light emitting region 33AA and the light emitting unit 33P in the first light emitting region 33BA, a set of the light emitting units 33P in the second main light emitting region 33AB and the light emitting unit 33P in the second light emitting region 33BB, a set of the light emitting units 33P in the third main light emitting region 33AC and the light emitting unit 33P in the third light emitting region 33BC, and a set of the light emitting units 33P in the fourth main light emitting region 33AD and the light emitting unit 33P in the fourth light emitting region 33BD individually emit laser light.

In addition, since the distance between the first electrode 34A and the first main light emitting region 33AA in the X direction is large, the wire W1C can be formed closer to the first electrode 34A than the first main light emitting region 33AA in plan view. Since the distance between the second electrode 34B and the second main light emitting region 33AB in the X direction is large, the wire W1D can be formed closer to the second electrode 34B than the second main light emitting region 33AB in plan view.

Although not illustrated, the semiconductor light emitting device 10 includes the reflecting portion 70 (see FIG. 3). The positional relationship between the reflecting portion 70 and the surface emitting laser chip 30 and the light receiving chip 40 is similar to that of the first embodiment. The configuration of the reflecting portion 70 and the configuration of the sealing member 50 related to the reflecting portion 70 are similar to those of the first embodiment.

### Advantages

According to the semiconductor light emitting device of the eighth embodiment, the following advantages are obtained.

(8-1) Each of the first to fourth light emitting regions 33BA to 33BD and the first to fourth main light emitting regions 33AA to 33AD includes the light emitting unit 33P that emits laser light. The first electrode 34A is electrically connected to both the light emitting unit 33P in the first light emitting region 33BA and the light emitting units 33P in the first main light emitting region 33AA. The second electrode 34B is electrically connected to both the light emitting unit 33P in the second light emitting region 33BB and the light emitting units 33P in the second main light emitting region 33AB. The third electrode 34C is electrically connected to both the light emitting unit 33P in the third light emitting region 33BC and the light emitting units 33P in the third main light emitting region 33AC. The fourth electrode 34D is electrically connected to both the light emitting unit 33P in the fourth light emitting region 33BD and the light emitting units 33P in the fourth main light emitting region 33AD.

According to this configuration, it is possible to achieve such a configuration that a set of the light emitting units 33P in the first main light emitting region 33AA and the light emitting unit 33P in the first light emitting region 33BA, a set of the light emitting units 33P in the second main light emitting region 33AB and the light emitting unit 33P in the second light emitting region 33BB, a set of the light emitting units 33P in the third main light emitting region 33AC and the light emitting unit 33P in the third light emitting region 33BC, and a set of the light emitting units 33P in the fourth main light emitting region 33AD and the light emitting unit 33P in the fourth light emitting region 33BD individually emit laser light. As a result, the outputs of the beams of laser light of the light emitting units 33P in the first main light emitting region 33AA can be controlled based on the amount of light received by the light receiving chip 40 for at least a part of the reflected light obtained by reflecting the laser light from the first light emitting region 33BA by the reflecting portion 70. In addition, the outputs of the beams of laser light of the light emitting units 33P in the second to fourth main light emitting regions 33AB to 33AD can be similarly controlled. As described above, the outputs of the beams of laser light from the light emitting units 33P in the first main light emitting region 33AA, the light emitting units 33P in the second main light emitting region 33AB, the light emitting units 33P in the third main light emitting region 33AC, and the light emitting units 33P in the fourth main light emitting region 33AD can be individually controlled.

(8-2) In plan view, the area of the first light emitting region 33BA is smaller than the area of the first main light emitting region 33AA. In plan view, the area of the second light emitting region 33BB is smaller than the area of the second main light emitting region 33AB. In plan view, the area of the third light emitting region 33BC is smaller than the area of the third main light emitting region 33AC. In plan view, the area of the fourth light emitting region 33BD is smaller than the area of the fourth main light emitting region 33AD.

According to this configuration, the outputs of the beams of laser light from the first to fourth light emitting regions 33BA to 33BD are smaller than the outputs of the beams of laser light from the first to fourth main light emitting regions 33AA to 33AD. Therefore, for example, the laser light from the first to fourth light emitting regions 33BA to 33BD can be employed in a configuration in which an output of laser light is small such that the laser light is reflected by the reflecting portion 70 and received by the light receiving chip 40. In addition, the laser light from the first to fourth main light emitting regions 33AA to 33AD can be employed in a configuration in which an output of laser light is large such that the laser light is emitted from the semiconductor light emitting device 10.

(8-3) Each of the first to fourth light emitting regions 33BA to 33BD and the first to fourth main light emitting regions 33AA to 33AD includes the light emitting unit 33P that emits laser light. The number of the light emitting units 33P in the first light emitting region 33BA is smaller than the number of the light emitting units 33P in the first main light emitting region 33AA. The number of the light emitting units 33P in the second light emitting region 33BB is smaller than the number of the light emitting units 33P in the second main light emitting region 33AB. The number of the light emitting units 33P in the third light emitting region 33BC is smaller than the number of the light emitting units 33P in the third main light emitting region 33AC. The number of the light emitting units 33P in the fourth light emitting region 33BD is smaller than the number of the light emitting units 33P in the fourth main light emitting region 33AD.

According to this configuration, the outputs of the beams of laser light from the first to fourth light emitting regions 33BA to 33BD are smaller than the outputs of the beams of laser light from the first to fourth main light emitting regions 33AA to 33AD. Therefore, for example, the laser light from the first to fourth light emitting regions 33BA to 33BD can be employed in a configuration in which an output of laser light is small such that the laser light is reflected by the reflecting portion 70 and received by the light receiving chip 40. In addition, the laser light from the first to fourth main light emitting regions 33AA to 33AD can be employed in a configuration in which an output of laser light is large such that the laser light is emitted from the semiconductor light emitting device 10.

(8-4) The shape of the first light emitting surface 33A in plan view is a circular shape.

According to this configuration, for example, even if the wires W1C and W1D joined to the third electrode 34C and the fourth electrode 34D are formed in an oblique direction intersecting with both the X direction and the Y direction in plan view, it is possible to prevent the wires W1C and W1D from overlapping with the light emitting unit 33P on the first light emitting surface 33A in plan view. In addition, since the laser light from the first light emitting surface 33A has a circular shape in plan view, the laser light can be efficiently used for a member of an optical system such as a lens. For example, when laser light is condensed using a lens, the condensing efficiency is enhanced.

### Modifications

Each of the above embodiments can be modified as follows and implemented. In addition, each of the above embodiments and each of the following modifications can be implemented in combination with each other within a range not technically contradictory.

The first to eighth embodiments can be combined with each other within a range not technically contradictory. Combinations of the first to eighth embodiments will now be described below.

The reflecting portion 70 of each of the third and fourth embodiments may be changed to the reflecting portion 70 of the first embodiment.

The reflecting portion 70 of each of the sixth to eighth embodiments may be changed to the reflecting portion 70 of the second embodiment.

The reflecting portion 70 of the third, fourth, and sixth to eighth embodiments may be changed to the reflecting portion 70 (diffusing material 72) of the fifth embodiment.

The semiconductor light emitting device 10 of the third, fourth, and sixth to eighth embodiments may include the reflecting portion 70 of the first embodiment or the second embodiment formed on the sealing surface 51 of the sealing member 50 and the diffusing material 72 of the fifth embodiment.

The surface emitting laser chip 30 of the first and third to fifth embodiments may be changed to any one of the surface emitting laser chips 30 of the sixth to eighth embodiments.

The semiconductor light emitting device 10 of the fifth embodiment may include the diffusing material 72 as the reflecting portion 70 and the reflecting portion 70 of the first embodiment or the second embodiment formed on the sealing surface 51 of the sealing member 50.

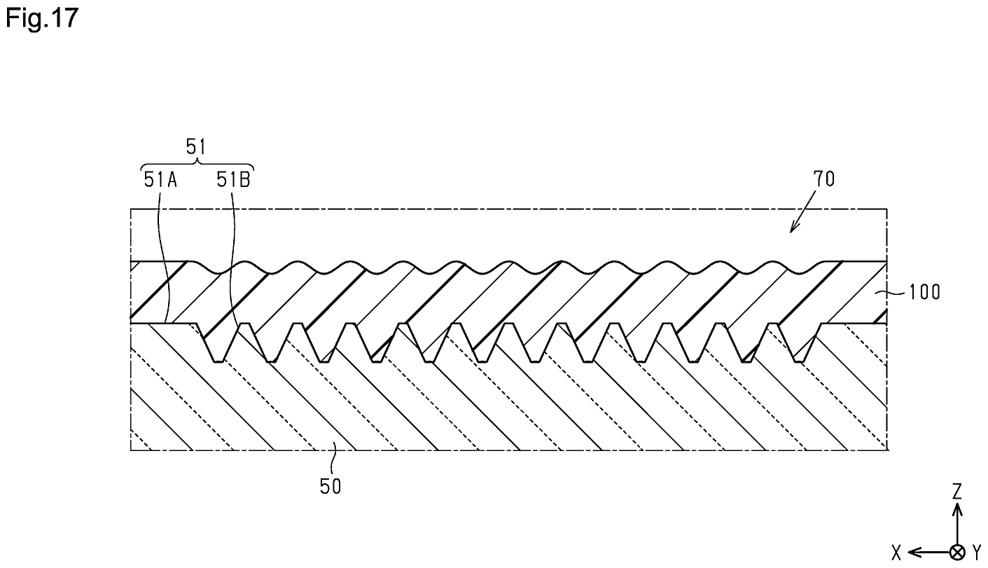

In the first embodiment, as illustrated in FIG. 17, a light shielding layer 100 may be formed on the rough surface 51B as the reflecting portion 70. The light shielding layer 100 may be formed of, for example, a resin material having a light shielding property. As the resin material having a light shielding property, for example, a black epoxy resin is used. Furthermore, the light shielding layer 100 may be formed of, for example, a metal film. Furthermore, the light shielding layer 100 may be formed of an anti-reflection coating (AR coating).

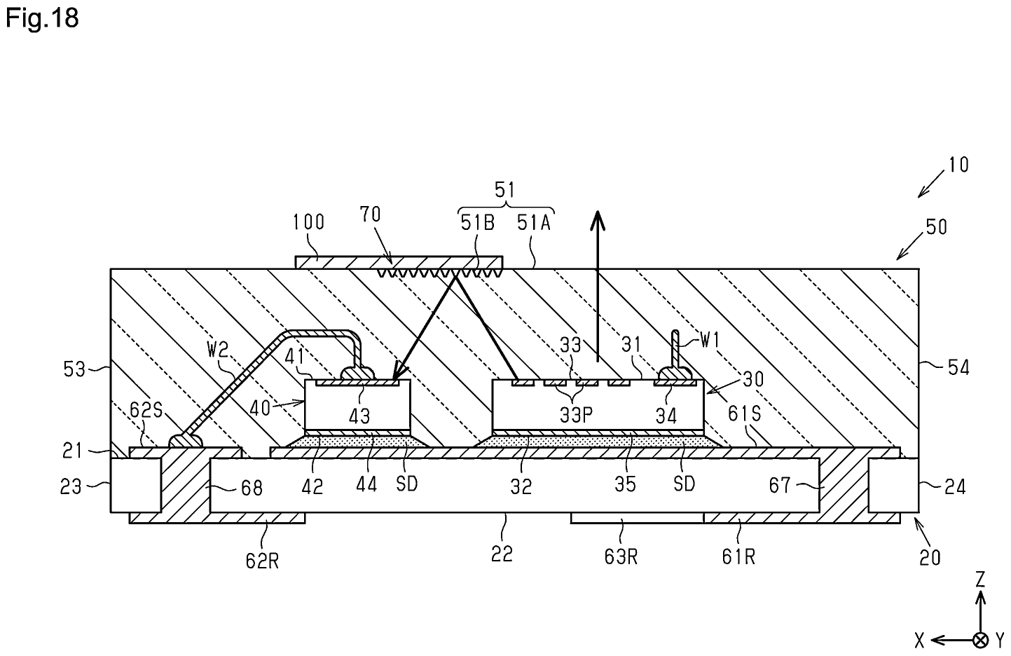

In the first and second embodiments, as illustrated in FIG. 18, the semiconductor light emitting device 10 may include the light shielding layer 100 formed in a portion of the sealing surface 51 of the sealing member 50 overlapping with the second chip front surface 41 as the light receiving surface in plan view. In the example illustrated in FIG. 18, the light shielding layer 100 covers the entire second chip front surface 41 (light receiving surface). As long as the light shielding layer 100 covers the second chip front surface 41 (light receiving surface), for example, the light shielding layer 100 does not necessarily need to cover at least a part of the reflecting portion 70.

In each embodiment, the material constituting the sealing member 50 can be changed. In one example, the sealing member 50 may be formed of a material that blocks visible light and transmits laser light having a specific wavelength different from visible light. The laser light having the specific wavelength is, for example, an ultraviolet laser. As a material constituting the sealing member 50, for example, a visible light shielding silicone sealing material may be used. As the sealing material, AIR-7051-A/B (manufactured by Shin-Etsu Chemical Co., Ltd.) may be used, for example. In this case, the surface emitting laser chip 30 is configured to emit laser light having a specific wavelength. The reflecting portion 70 is configured to reflect laser light having a specific wavelength.

In the first to fifth embodiments, the position of the reflecting portion 70 in plan view can be changed. In one example, the reflecting portion 70 may be arranged at a position overlapping with a part of the light emitting surface 33 of the surface emitting laser chip 30 in plan view.

In the first, second, and fifth to eighth embodiments, the arrangement of the surface emitting laser chip 30 and the light receiving chip 40 can be changed. In one example, the surface emitting laser chip 30 and the light receiving chip 40 may be arranged to be shifted from each other in the Y direction.

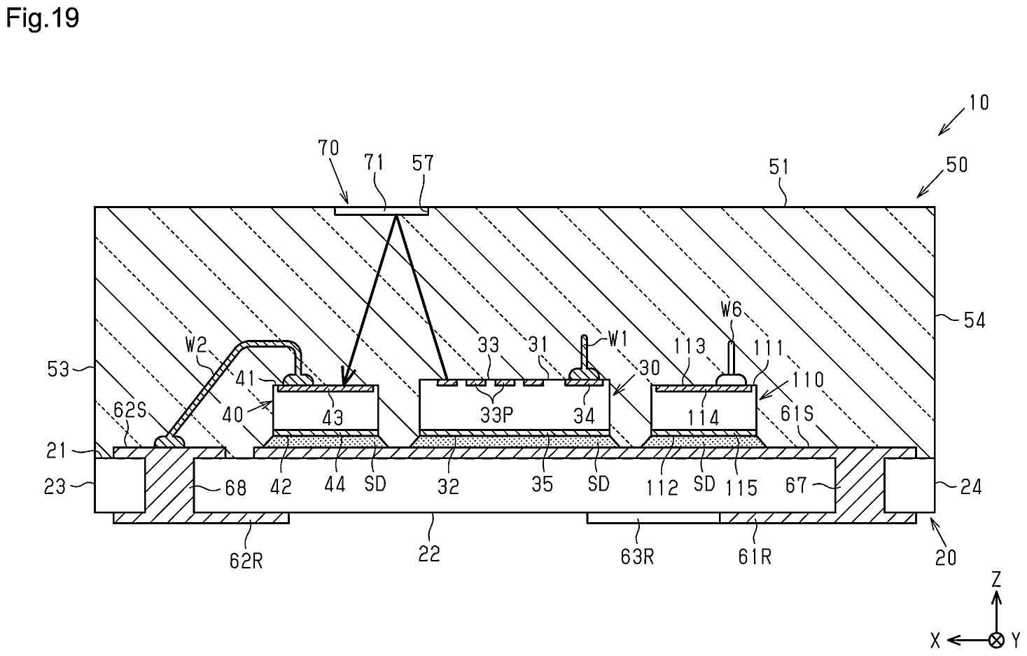

In the first, second, and sixth to eighth embodiments, the semiconductor light emitting device 10 may include a detection light receiving chip 110 that is configured to receive reflected light that is the laser light emitted from the surface emitting laser chip 30 and reflected by the object DT. In one example, as illustrated in FIG. 19, the detection light receiving chip 110 is arranged on the side opposite to the light receiving chip 40 with respect to the surface emitting laser chip 30 in the X direction. The detection light receiving chip 110 includes, for example, a photodiode.

The detection light receiving chip 110 includes a third chip front surface 111 and a third chip back surface 112 facing opposite sides in the Z direction. The third chip front surface 111 faces the same side as the substrate front surface 21, and the third chip back surface 112 faces the same side as the substrate back surface 22. A light receiving surface 113 is formed on the third chip front surface 111. A front electrode 114 is formed on the light receiving surface 113. A back electrode 115 is formed on the third chip back surface 112.

The detection light receiving chip 110 is bonded to the first front electrode 61S by the conductive bonding material SD. As a result, the back electrode 115 of the detection light receiving chip 110 is electrically connected to the first front electrode 61S via the conductive bonding material SD.

A wire W6 is formed on the front electrode 114 of the detection light receiving chip 110. The wire W6 is connected to the second front electrode 62S. Thus, the front electrode 114 is electrically connected to the second front electrode 62S via the wire W6.

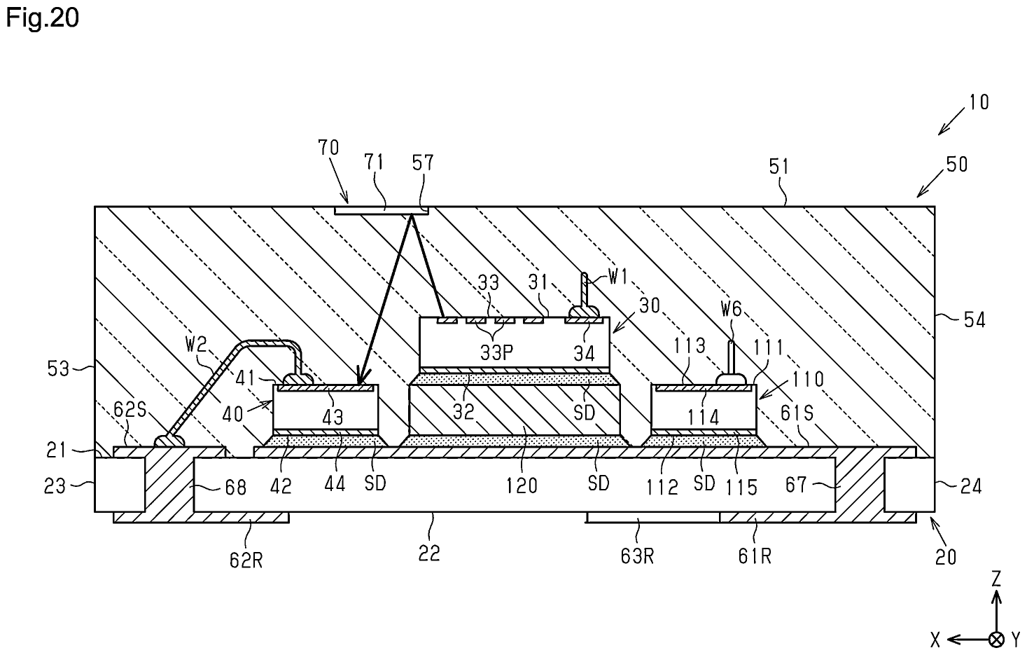

In the modification illustrated in FIG. 19, the arrangement of the surface emitting laser chip 30 can be changed. In one example, as illustrated in FIG. 20, the semiconductor light emitting device 10 may include a submount substrate 120 interposed between the substrate 20 and the surface emitting laser chip 30 in the Z direction.

The submount substrate 120 is formed in a rectangular flat plate shape with the Z direction as a thickness direction. The submount substrate 120 is formed of, for example, a conductive material. As the conductive material, for example, Cu, Al, or the like is used. In one example, the submount substrate 120 is formed of Cu.

The submount substrate 120 is bonded to the first front electrode 61S by the conductive bonding material SD. The surface emitting laser chip 30 is bonded to the submount substrate 120 by the conductive bonding material SD. As a result, the back electrode 35 of the surface emitting laser chip 30 is electrically connected to the first front electrode 61S via the submount substrate 120 and the conductive bonding material SD.

In the example illustrated in FIG. 20, the light emitting surface 33 of the surface emitting laser chip 30 is arranged such that the first chip back surface 32 of the surface emitting laser chip 30 is closer to the sealing surface 51 than the light receiving surface 113 of the detection light receiving chip 110. By adjusting the thickness of the submount substrate 120, the first chip back surface 32 of the surface emitting laser chip 30 may be arranged closer to the substrate 20 than the light receiving surface 113 of the detection light receiving chip 110.

According to the configuration of the modification illustrated in FIG. 20, heat of the surface emitting laser chip 30 readily moves to the substrate 20 via the submount substrate 120. Therefore, it is possible to prevent the temperature of the surface emitting laser chip 30 from becoming excessively high.

The submount substrate 120 may be formed of a material containing an insulating material. Examples of the insulating material include ceramics and resin materials. As the ceramic, AlN or Al₂O₃ can be used. In this case, the submount substrate 120 includes one or multiple through wirings extending through the submount substrate 120 in the Z direction. The back electrode 35 of the surface emitting laser chip 30 and the first front electrode 61S are electrically connected via one or multiple through wirings. When ceramic is used as the insulating material of the submount substrate 120, heat of the surface emitting laser chip 30 readily moves to the substrate 20 via the submount substrate 120. Therefore, it is possible to prevent the temperature of the surface emitting laser chip 30 from becoming excessively high. The submount substrate 120 may be formed of a semiconductor material such as silicon (Si). Also in this case, the submount substrate 120 includes one or multiple through wirings extending through the submount substrate 120 in the Z direction.

In the modification illustrated in FIGS. 19 and 20, the sealing member 50 may include a slit extending in the Y direction and the Z direction, with the Z direction representing the depth direction. The slit may be formed between the surface emitting laser chip 30 and the detection light receiving chip 110 in the X direction. This slit may be, for example, the same as the slit 58 of the fourth embodiment.

In the sixth and seventh embodiments, the relationship between the area of the first light emitting surface 33A and the area of the second light emitting surface 33B in the surface emitting laser chip 30 can be changed. In one example, the area of the first light emitting surface 33A and the area of the second light emitting surface 33B may be equal to each other.

In the sixth and seventh embodiments, the relationship between the number of the light emitting units 33P on the first light emitting surface 33A and the number of the light emitting units 33P on the second light emitting surface 33B in the surface emitting laser chip 30 can be changed. In one example, the number of the light emitting units 33P on the first light emitting surface 33A and the number of the light emitting units 33P on the second light emitting surface 33B may be equal to each other.

In the seventh embodiment, the arrangement of the first electrode 34A and the second electrode 34B can be changed. In one example, the first electrode 34A and the second electrode 34B may be arranged to be separated from each other in the X direction. In one example, the second electrode 34B may be arranged between the first light emitting surface 33A and the second light emitting surface 33B in the X direction, while the first electrode 34A may be arranged on the side opposite to the second light emitting surface 33B with respect to the first light emitting surface 33A in the X direction.

In the seventh embodiment, in plan view, the relationship between the area of the first electrode 34A and the area of the second electrode 34B can be changed. In one example, the area of the first electrode 34A and the area of the second electrode 34B may be equal to each other.

In the eighth embodiment, the relationship between the areas of the first to fourth main light emitting regions 33AA to 33AD of the first light emitting surface 33A can be changed. In one example, the areas of the first to fourth main light emitting regions 33AA to 33AD may be equal to each other.

In the eighth embodiment, the lengths in the X direction of the first to fourth main light emitting regions 33AA to 33AD of the first light emitting surface 33A can be changed. In one example, the lengths in the X direction of the first to fourth main light emitting regions 33AA to 33AD may be equal to each other.

In the eighth embodiment, the relationship between the numbers of light emitting units 33P in the first to fourth main light emitting regions 33AA to 33AD of the first light emitting surface 33A can be changed. In one example, the number of the light emitting units 33P in the first to fourth main light emitting regions 33AA to 33AD may be the same.

In the eighth embodiment, the relationship between the areas of the first to fourth main light emitting regions 33AA to 33AD of the first light emitting surface 33A and the areas of the first to fourth light emitting regions 33BA to 33BD of the second light emitting surface 33B can be changed. In one example, the area of the first main light emitting region 33AA and the area of the first light emitting region 33BA may be equal to each other. In one example, the area of the second main light emitting region 33AB and the area of the second light emitting region 33BB may be equal to each other. In one example, the area of the third main light emitting region 33AC and the area of the third light emitting region 33BC may be equal to each other. In one example, the area of the fourth main light emitting region 33AD and the area of the fourth light emitting region 33BD may be equal to each other.

In the eighth embodiment, the relationship between the number of the light emitting units 33P in the first to fourth main light emitting regions 33AA to 33AD of the first light emitting surface 33A and the number of the light emitting units 33P in the first to fourth light emitting regions 33BA to 33BD of the second light emitting surface 33B can be changed. In one example, the number of the light emitting units 33P in the first main light emitting region 33AA and the number of the light emitting units 33P in the first light emitting region 33BA may be the same. In one example, the number of the light emitting units 33P in the second main light emitting region 33AB and the number of the light emitting units 33P in the second light emitting region 33BB may be the same. In one example, the number of the light emitting units 33P in the third main light emitting region 33AC and the number of the light emitting units 33P in the third light emitting region 33BC may be the same. In one example, the number of the light emitting units 33P in the fourth main light emitting region 33AD and the number of the light emitting units 33P in the fourth light emitting region 33BD may be the same.

In the eighth embodiment, the arrangement of the first to fourth light emitting regions 33BA to 33BD of the second light emitting surface 33B can be changed. In one example, the first to fourth light emitting regions 33BA to 33BD may be arranged to be separated from each other in both the X direction and the Y direction. That is, the first to fourth light emitting regions 33BA to 33BD may be arranged in a lattice pattern in plan view.

In the eighth embodiment, the arrangement of the first to fourth main light emitting regions 33AA to 33AD of the first light emitting surface 33A, the first to fourth light emitting regions 33BA to 33BD of the second light emitting surface 33B, and the first to fourth electrodes 34A to 34D can be changed. In one example, the first main light emitting region 33AA, the first light emitting region 33BA, and the first electrode 34A may be arranged at positions shifted from each other in the Y direction. In one example, the second main light emitting region 33AB, the second light emitting region 33BB, and the second electrode 34B may be arranged at positions shifted from each other in the Y direction. In one example, the third main light emitting region 33AC, the third light emitting region 33BC, and the third electrode 34C may be arranged at positions shifted from each other in the Y direction. In one example, the fourth main light emitting region 33AD, the fourth light emitting region 33BD, and the fourth electrode 34D may be arranged at positions shifted from each other in the Y direction.

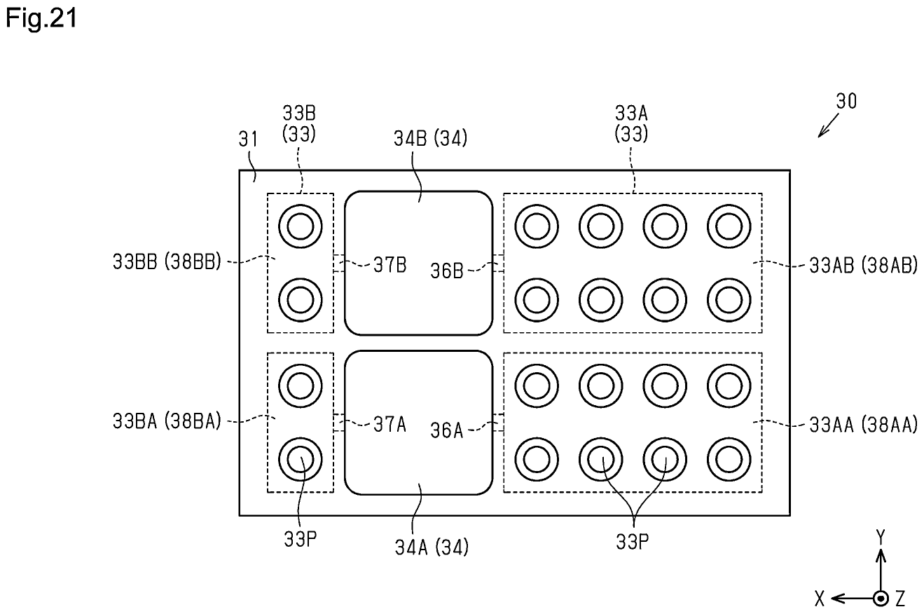

In the surface emitting laser chip 30 of the eighth embodiment, the numbers of light emitting regions of the first light emitting surface 33A and the second light emitting surface 33B can be changed. In one example, as illustrated in FIG. 21, each of the first light emitting surface 33A and the second light emitting surface 33B may include two light emitting regions. That is, the first light emitting surface 33A may include the first main light emitting region 33AA and the second main light emitting region 33AB arranged to be separated from each other. The second light emitting surface 33B may include the first light emitting region 33BA and the second light emitting region 33BB arranged to be separated from each other. In this case, the front electrode 34 may include the first electrode 34A and the second electrode 34B arranged to be separated from each other.

In the example illustrated in FIG. 21, the first main light emitting region 33AA and the second main light emitting region 33AB are arranged at the same position in the X direction and are separated from each other in the Y direction. The first light emitting region 33BA and the second light emitting region 33BB are arranged at the same position in the X direction and to be separated from each other in the Y direction. The first light emitting region 33BA is arranged at the same position as the first main light emitting region 33AA in the Y direction. The second light emitting region 33BB is arranged at the same position as the second main light emitting region 33AB in the Y direction.

In plan view, the area of the first light emitting region 33BA is smaller than the area of the first main light emitting region 33AA. More specifically, the length of the first light emitting region 33BA in the X direction is shorter than the length of the first main light emitting region 33AA in the X direction. The length of the first light emitting region 33BA in the Y direction is equal to the length of the first main light emitting region 33AA in the Y direction. Both the first light emitting region 33BA and the first main light emitting region 33AA include multiple light emitting units 33P. The number of the light emitting units 33P in the first light emitting region 33BA is smaller than the number of the light emitting units 33P in the first main light emitting region 33AA. The light emitting units 33P in the first light emitting region 33BA are arranged at the same position in the X direction and to be separated from each other in the Y direction. That is, the light emitting units 33P in the first light emitting region 33BA are arranged in one row in the Y direction. The light emitting units 33P in the first main light emitting region 33AA are arranged to be separated from each other in both the X direction and the Y direction.

In plan view, the area of the second light emitting region 33BB is smaller than the area of the second main light emitting region 33AB. More specifically, the length of the second light emitting region 33BB in the X direction is shorter than the length of the second main light emitting region 33AB in the X direction. The length of the second light emitting region 33BB in the Y direction is equal to the length of the second main light emitting region 33AB in the Y direction.

Both the second light emitting region 33BB and the second main light emitting region 33AB include multiple light emitting units 33P. The number of the light emitting units 33P in the second light emitting region 33BB is smaller than the number of the light emitting units 33P in the second main light emitting region 33AB. The light emitting units 33P in the second light emitting region 33BB are arranged at the same position in the X direction and to be separated from each other in the Y direction. That is, the light emitting units 33P in the second light emitting region 33BB are arranged in one row in the Y direction. The light emitting units 33P in the second main light emitting region 33AB are arranged to be separated from each other in both the X direction and the Y direction. In one example, the number of the light emitting units 33P in the second main light emitting region 33AB is the same as the number of the light emitting units 33P in the first main light emitting region 33AA. In one example, the number of the light emitting units 33P in the second light emitting region 33BB is the same as the number of the light emitting units 33P in the first light emitting region 33BA.

The regions of the broken line frames defining the first main light emitting region 33AA and the second main light emitting region 33AB are the same as the outer frames of the first light emitting electrode 38AA and the second light emitting electrode 38AB electrically connected to each light emitting unit 33P. That is, in plan view, the region surrounded by the outer frame of the first light emitting electrode 38AA is referred to as a first main light emitting region 33AA, and the region surrounded by the outer frame of the second light emitting electrode 38AB is referred to as a second main light emitting region 33AB.

Further, the regions of the broken line frames defining the first light emitting region 33BA and the second light emitting region 33BB are the same as the outer frames of the first light emitting electrode 38BA and the second light emitting electrode 38BB electrically connected to each light emitting unit 33P. That is, in plan view, the region surrounded by the outer frame of the first light emitting electrode 38BA is referred to as a first light emitting region 33BA, and the region surrounded by the outer frame of the second light emitting electrode 38BB is referred to as a second light emitting region 33BB.

The areas and the numbers of light emitting units 33P in the first main light emitting region 33AA, the second main light emitting region 33AB, the first light emitting region 33BA, and the second light emitting region 33BB can be changed.

The first electrode 34A and the second electrode 34B are arranged at the same position in the X direction and to be separated from each other in the Y direction. The first electrode 34A is arranged at the same position as the first main light emitting region 33AA and the first light emitting region 33BA in the Y direction. The second electrode 34B is arranged at the same position as the second main light emitting region 33AB and the second light emitting region 33BB in the Y direction.

The first electrode 34A is electrically connected to the light emitting units 33P in the first main light emitting region 33AA and the light emitting units 33P in the first light emitting region 33BA. More specifically, the surface emitting laser chip 30 includes a first connecting portion 36A that electrically connects the first electrode 34A and the light emitting units 33P in the first main light emitting region 33AA, and a second connecting portion 37A that electrically connects the first electrode 34A and the light emitting units 33P in the first light emitting region 33BA. Therefore, the surface emitting laser chip 30 is configured such that the light emitting units 33P in the first main light emitting region 33AA and the light emitting units 33P in the first light emitting region 33BA simultaneously emit laser light via the first electrode 34A, the first connecting portion 36A, and the second connecting portion 37A.

The second electrode 34B is electrically connected to the light emitting units 33P in the second main light emitting region 33AB and the light emitting units 33P in the second light emitting region 33BB. More specifically, the surface emitting laser chip 30 includes a first connecting portion 36B that electrically connects the second electrode 34B and the light emitting units 33P in the second main light emitting region 33AB, and a second connecting portion 37B that electrically connects the second electrode 34B and the light emitting units 33P in the second light emitting region 33BB. Therefore, the surface emitting laser chip 30 is configured such that the light emitting units 33P in the second main light emitting region 33AB and the light emitting units 33P in the second light emitting region 33BB simultaneously emit laser light via the second electrode 34B, the first connecting portion 36B, and the second connecting portion 37B.

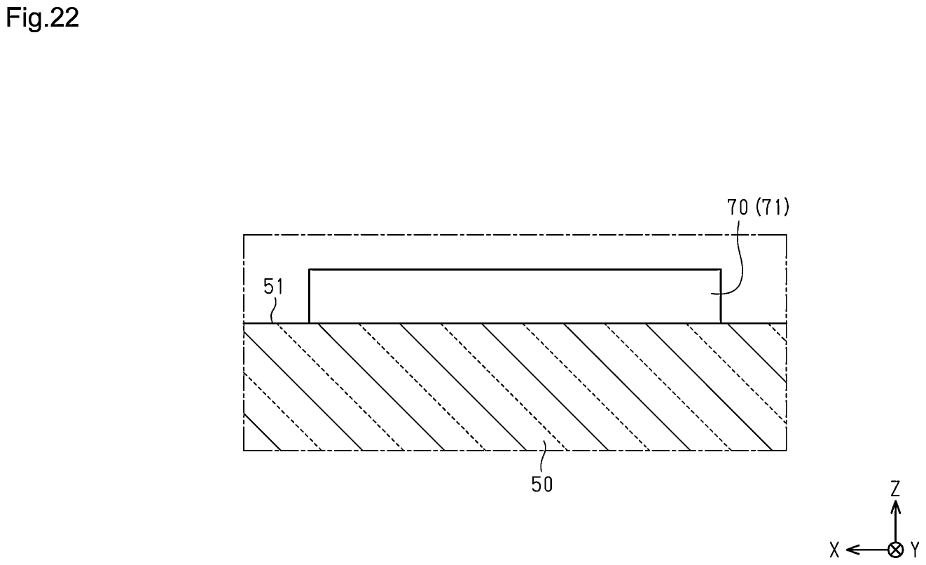

In the second embodiment, the recess 57 may be omitted from the sealing member 50. In this case, as illustrated in FIG. 22, the reflecting layer 71 of the reflecting portion 70 is formed on the sealing surface 51.

In each embodiment, the reflecting portion 70 may be formed between the surface emitting laser chip 30 and the light receiving chip 40 in the X direction. That is, in plan view, the reflecting portion 70 may be arranged closer to the light receiving chip 40 than the first chip front surface 31 of the surface emitting laser chip 30 to be separated from the surface emitting laser chip 30 in the X direction. In plan view, the reflecting portion 70 may be arranged to be closer to the surface emitting laser chip 30 than to the light receiving chip 40 in the X direction.

One or more of the various examples described herein may be combined to the extent that they are not technically inconsistent.

Terms such as “first”, “second”, and “third” in this disclosure are used to distinguish subjects and not used for ordinal purposes.

In this specification, “at least one of A and B” should be understood to mean “only A, or only B, or both A and B.”

In the present disclosure, the term “on” includes the meaning of “above” in addition to the meaning of “on” unless otherwise clearly indicated in the context. Therefore, for example, the phrase “first component disposed on second component” is intended to mean that the first component may be disposed on the second component in contact with the second component in one embodiment and that the first component may be disposed above the second component without contacting the second component in another embodiment. In other words, the term “on” does not exclude a structure in which another component is formed between the first component and the second component.

The Z-direction referred to in the present disclosure does not necessarily have to be the vertical direction and does not necessarily have to exactly coincide with the vertical direction. In the structures according to the present disclosure, “upward” and “downward” in the z-direction as referred to in the present description are not limited to “upward” and “downward” in the vertical direction. For example, the X-direction may conform to the vertical direction. The Y-direction may conform to the vertical direction.

### CLAUSES

The technical concepts described below may be recognized from the present disclosure. For aid in understanding and not for limitation, the reference numerals of corresponding components in the embodiment are given to components described in the clauses. The reference numerals are given as examples to aid understanding, and the components described in each clause should not be limited to the components indicated by the reference numerals.

### Clause A1

A semiconductor light emitting device (10), including:
a surface emitting laser chip (30) having a light emitting surface (33) and configured to emit laser light from the light emitting surface (33);
a light receiving chip (40);
a sealing member (50) that is formed of a material through which the laser light can pass and seals the surface emitting laser chip (30) and the light receiving chip (40); and
a reflecting portion (70) that is provided in the sealing member (50) and reflects a part of the laser light toward the light receiving chip (40),
in which the light receiving chip (40) is arranged at a position where the light receiving chip (40) receives at least a part of reflected light by the reflecting portion (70).

### Clause A2

The semiconductor light emitting device according to Clause A1, in which the reflecting portion (70) includes irregularities formed on a part of a sealing surface (51) of the sealing member (50).

### Clause A3

The semiconductor light emitting device according to Clause A2, in which
the sealing surface (51) of the sealing member (50) includes a flat surface (51A) and a rough surface (51B) rougher than the flat surface (51A), and
the reflecting portion (70) includes the rough surface (51B).

### Clause A4

The semiconductor light emitting device according to Clause A1, in which the reflecting portion (70) includes a reflecting layer (71) formed on a sealing surface (51) of the sealing member (50).

### Clause A5

The semiconductor light emitting device according to Clause A1, in which
the sealing member (50) includes a sealing surface (51) through which the laser light passes, and a recess (57) formed in a part of the sealing surface (51), and
the reflecting portion (70) includes a reflecting layer (71) provided in the recess (57).

### Clause A6

The semiconductor light emitting device according to any one of Clauses A1 to A5, further including a light shielding layer (100) formed in a portion of the sealing surface (51) of the sealing member (50), the portion overlapping with the light receiving chip (40) as viewed in a direction (Z direction) perpendicular to the sealing surface (51).

### Clause A7

The semiconductor light emitting device according to Clause A6, in which the light shielding layer (100) covers the reflecting portion (70).

### Clause A8

The semiconductor light emitting device according to any one of Clauses A1 to A7, in which
the light emitting surface (33) of the surface emitting laser chip (30) and the light receiving surface (41) of the light receiving chip (40) are arranged to be separated from each other in a first direction (X direction) as viewed in a direction (Z direction) perpendicular to a sealing surface (51) of the sealing member (50), and
the reflecting portion (70) is formed between the light emitting surface (33) and the light receiving surface (41) in the first direction (X direction) as viewed from the direction (Z direction) perpendicular to the sealing surface (51).

### Clause A9

The semiconductor light emitting device according to Clause A8, in which the reflecting portion (70) is provided so as to extend over the surface emitting laser chip (30) and the light receiving chip (40) in the first direction (X direction) as viewed from the direction (Z direction) perpendicular to the sealing surface (51).

### Clause A10

The semiconductor light emitting device according to any one of Clauses A1 to A9, in which
a chip front surface (31) of the surface emitting laser chip (30) includes the light emitting surface (33) and an electrode (34) formed to be separated from the light emitting surface (33) in a first direction (X direction) as viewed from a direction (Z direction) perpendicular to the chip front surface (31), and
the light receiving chip (40) is arranged on a side opposite to the electrode (34) with respect to the light emitting surface (33) in the first direction (X direction).

### Clause A11

The semiconductor light emitting device according to any one of Clauses A1 to A10, further including a substrate (20), in which
the surface emitting laser chip (30) is arranged on the substrate (20), and
the light receiving chip (40) is arranged on the substrate (20) to be separated from the surface emitting laser chip (30) in a first direction (X direction) as viewed from a thickness direction (Z direction) of the substrate (20).

### Clause A12

The semiconductor light emitting device according to Clause A11, further including a detection light receiving chip (110) that is arranged on the substrate (20) and is configured to receive reflected light that is the laser light emitted from the surface emitting laser chip (30) and reflected by an object (DT),
in which the detection light receiving chip (110) is arranged on a side opposite to the light receiving chip (40) with respect to the surface emitting laser chip (30) in the first direction (X direction).

### Clause A13

The semiconductor light emitting device according to Clause A11, further including a submount substrate (120) interposed between the substrate (20) and the surface emitting laser chip (30) in the thickness direction (Z direction) of the substrate (20).

### Clause A14

The semiconductor light emitting device according to Clause A13, further including a detection light receiving chip (110) that is arranged on the substrate (20) and is configured to receive reflected light that is the laser light emitted from the surface emitting laser chip (30) and reflected by an object (DT), in which
the surface emitting laser chip (30) includes a chip back surface (32) opposite to the light emitting surface (33) in the thickness direction (Z direction), and
the detection light receiving chip (110) is arranged closer to the substrate (20) than the chip back surface (32) is in the thickness direction (Z direction).

### Clause A15

The semiconductor light emitting device according to any one of Clauses A1 to A10, in which
the light receiving chip (80) includes a light receiving element (95) and a chip front surface (81),
the chip front surface (81) includes a light receiving surface (95A) of the light receiving element (95), and
the surface emitting laser chip (30) is bonded to the chip front surface (81) of the light receiving chip (80), and the surface emitting laser chip (30) is arranged at a position different from the light receiving surface (95A) of the light receiving element (95) as viewed from a direction (Z direction) perpendicular to the chip front surface (81).

### Clause A16

The semiconductor light emitting device according to Clause A15, in which
the light receiving chip (80) further includes a detection light receiving element (96) that is configured to receive reflected light that is the laser light emitted from the surface emitting laser chip (30) and reflected by an object (DT), and
the detection light receiving element (96) is formed on a side opposite to the light receiving element (95) with respect to the surface emitting laser chip (30) in a first direction (X direction) of the light receiving chip (80) as viewed from a direction (Z direction) perpendicular to the chip front surface (81).

### Clause A17

The semiconductor light emitting device according to Clause A16, in which
a direction orthogonal to the first direction (X direction) as viewed from a direction (Z direction) perpendicular to the chip front surface (81) is defined as a second direction (Y direction), and
the sealing member (50) includes a slit (58) extending in the second direction (Y direction) and a depth direction (Z direction) perpendicular to the chip front surface (81) and being formed between the surface emitting laser chip (30) and a detection surface (96A) of the detection light receiving element (96) in the first direction (X direction).

### Clause A18

The semiconductor light emitting device according to any one of Clauses A1 to A17, in which the reflecting portion (70) includes multiple diffusing materials (72) that are provided in the sealing member (50) and diffuse the laser light.

### Clause A19

The semiconductor light emitting device according to any one of Clauses A1 to A14, in which the light receiving chip (40) includes a photodiode.

### Clause A20

The semiconductor light emitting device according to any one of Clauses A1 to A19, in which
the surface emitting laser chip (30) is configured to emit laser light having a specific wavelength different from visible light, and
the sealing member (50) is made of a material that blocks the visible light and transmits the laser light having the specific wavelength.

### Clause A21

The semiconductor light emitting device according to any one of Clauses A1 to A14, in which the reflecting portion (70) is larger in area than a light receiving surface (41) of the light receiving chip (40) as viewed in the direction (Z direction) perpendicular to the sealing surface (51) of the sealing member (50).

### Clause A22

The semiconductor light emitting device according to any one of Clauses A1 to A14, in which a shape of the reflecting portion (70) as viewed from the direction (Z direction) perpendicular to the sealing surface (51) of the sealing member (50) is a rectangular shape.

### Clause A23

The semiconductor light emitting device according to Clause A22, in which
a direction orthogonal to the first direction (X direction) as viewed from the direction (Z direction) perpendicular to the sealing surface (51) of the sealing member (50) is defined as a second direction (Y direction), and
a length (LA) of the reflecting portion (70) in the second direction (Y direction) viewed from the direction (Z direction) perpendicular to the sealing surface (51) of the sealing member (50) is larger than a length (LB) of the light receiving surface (41) of the light receiving chip (40) in the second direction (Y direction) viewed from the direction (Z direction) perpendicular to the sealing surface (51) of the sealing member (50).

### Clause A24

The semiconductor light emitting device according to any one of Clauses A1 to A23, in which
the surface emitting laser chip (30) includes a first light emitting surface (33A) and a second light emitting surface (33B) on a chip front surface (31), each of the first light emitting surface (33A) and the second light emitting surface (33B) including multiple light emitting units (33P) as the light emitting surface (33),
the first light emitting surface (33A) and the second light emitting surface (33B) are formed at different positions as viewed from a direction (Z direction) perpendicular to the light emitting surface (33), and
the reflecting portion (70) is arranged to reflect light emitted from the light emitting units (33P) of the second light emitting surface (33B).

### Clause A25

The semiconductor light emitting device according to Clause A24, in which the first light emitting surface (33A) and the second light emitting surface (33B) are formed to be separated from each other in the first direction (X direction) as viewed from the direction (Z direction) perpendicular to the light emitting surface (33).

### Clause A26

The semiconductor light emitting device according to Clause A25, in which the surface emitting laser chip (30) includes an electrode (34) formed between the first light emitting surface (33A) and the second light emitting surface (33B) in the first direction (X direction).

### Clause A27

The semiconductor light emitting device according to any one of Clauses A24 to A26, in which the light receiving chip (40) is arranged on a side opposite to the first light emitting surface (33A) with respect to the second light emitting surface (33B) as viewed in the direction (Z direction) perpendicular to the light emitting surface (33).

### Clause A28

The semiconductor light emitting device according to any one of Clauses A24 to A27, in which an area of the second light emitting surface (33B) is smaller than an area of the first light emitting surface (33A).

### Clause A29

The semiconductor light emitting device according to Clause A28, in which the at least one light emitting unit (33P) included in the second light emitting surface (33B) is smaller in number than the at least one light emitting unit (33P) included in the first light emitting surface (33A).

### Clause A30

The semiconductor light emitting device according to any one of Clauses A24 to A29, in which the reflecting portion (70) is formed at a position overlapping with the second light emitting surface (33B) as viewed in the direction (Z direction) perpendicular to the light emitting surface (33).

### Clause A31

The semiconductor light emitting device according to any one of Clauses A15 to A17, in which the light receiving element (95) includes a photodiode.

### Clause A32

The semiconductor light emitting device according to any one of Clauses A15 to A17, in which the reflecting portion (70) is larger in area than the light receiving surface (95A) of the light receiving element (95) as viewed in the direction (Z direction) perpendicular to the sealing surface (51) of the sealing member (50).

### Clause A33

The semiconductor light emitting device according to any one of Clauses A15 to A17, in which a shape of the reflecting portion (70) as viewed from the direction (Z direction) perpendicular to the sealing surface (51) of the sealing member (50) is a rectangular shape.

### Clause A34

The semiconductor light emitting device according to any one of Clauses A12 to A14, in which
a direction orthogonal to the first direction (X direction) as viewed from the thickness direction (Z direction) is defined as a second direction (Y direction), and
the sealing member (50) includes a slit (58) extending in the second direction (Y direction) and the thickness direction (Z direction), with the Z direction representing a depth direction, the slit (58) being formed between the surface emitting laser chip (30) and the detection light receiving chip (110) in the first direction (X direction).

### Clause B1

A surface emitting laser chip (30), including:
a chip front surface (31) and a chip back surface (32) facing opposite sides;
a first light emitting surface (33A) and a second light emitting surface (33B) formed on the chip front surface (31) and configured to emit laser light; and
an electrode (34) formed on the chip front surface (31) and formed at a position separated from each of the first light emitting surface (33A) and the second light emitting surface (33B), in which
the first light emitting surface (33A) and the second light emitting surface (33B) are arranged to be separated from each other in a first direction (X direction) as viewed in a thickness direction (Z direction) perpendicular to the chip front surface (31), and
the electrode (34) is arranged between the first light emitting surface (33A) and the second light emitting surface (33B) in the first direction (X direction).

### Clause B2

The surface emitting laser chip according to Clause B1, in which an area of the second light emitting surface (33B) is smaller than an area of the first light emitting surface (33A) as viewed in the thickness direction (Z direction).

### Clause B3

The surface emitting laser chip according to Clause B2, in which
each of the first light emitting surface (33A) and the second light emitting surface (33B) includes at least one light emitting unit (33P) configured to emit laser light, and
the at least one light emitting unit (33P) of the second light emitting surface (33B) is smaller in number than the at least one light emitting unit (33P) of the first light emitting surface (33A).

### Clause B4

The surface emitting laser chip according to Clause B3, in which the electrode (34) is electrically connected to both the at least one light emitting unit (33P) of the first light emitting surface (33A) and the at least one light emitting unit (33P) of the second light emitting surface (33B).

### Clause B5

The surface emitting laser chip according to any one of Clauses B1 to B4, in which,
a direction orthogonal to the first direction (X direction) as viewed from the thickness direction (Z direction) is defined as a second direction (Y direction), and the second light emitting surface (33B) includes multiple light emitting units (33P) arranged to be separated from each other in the second direction (Y direction).

### Clause B6

The surface emitting laser chip according to Clause B1, in which
each of the first light emitting surface (33A) and the second light emitting surface (33B) includes a light emitting unit (33P) configured to emit laser light,
the electrode (34) includes a first electrode (34A) and a second electrode (34B) arranged to be separated from each other,
the first electrode (34A) is electrically connected to the light emitting unit (33P) of the first light emitting surface (33A), and
the second electrode (34B) is electrically connected to the light emitting unit (33P) of the second light emitting surface (33B).

### Clause B7

The surface emitting laser chip according to Clause B6, in which
a direction orthogonal to the first direction (X direction) as viewed from the thickness direction (Z direction) is defined as a second direction (Y direction), and
the first electrode (34A) and the second electrode (34B) are arranged to be separated from each other in the second direction (Y direction).

### Clause B8

The surface emitting laser chip according to Clause B6 or B7, in which an area of the first electrode (34A) is larger than an area of the second electrode (34B) as viewed in the thickness direction (Z direction).

### Clause B9

The surface emitting laser chip according to Clause B1, in which
the first light emitting surface (33A) includes a first main light emitting region (33AA) and a second main light emitting region (33AB) arranged to be separated from each other,
the second light emitting surface (33B) includes a first light emitting region (33BA) and a second light emitting region (33BB) arranged to be separated from each other, and
the electrode (34) includes a first electrode (34A) and a second electrode (34B) arranged to be separated from each other.

### Clause B10

The surface emitting laser chip according to Clause B9, in which
each of the first light emitting region (33BA), the second light emitting region (33BB), the first main light emitting region (33AA), and the second main light emitting region (33AB) includes a light emitting unit (33P) configured to emit laser light,
the first electrode (34A) is electrically connected to both the light emitting unit (33P) in the first light emitting region (33BA) and the light emitting unit (33P) of the first main light emitting region (33AA), and
the second electrode (34B) is electrically connected to both the light emitting unit (33P) in the second light emitting region (33BB) and the light emitting unit (33P) of the second main light emitting region (33AB).

### Clause B11

The surface emitting laser chip according to Clause B9 or B10, in which
a direction orthogonal to the first direction (X direction) as viewed from the thickness direction (Z direction) is defined as a second direction (Y direction),
the first light emitting region (33BA), the first main light emitting region (33AA), and the first electrode (34A) are provided at the same position in the second direction (Y direction), and
the second light emitting region (33BB), the second main light emitting region (33AB), and the second electrode (34B) are provided at the same position in the second direction (Y direction).

### Clause B12

The surface emitting laser chip according to any one of Clauses B9 to B11, in which
an area of the first light emitting region (33BA) is smaller than an area of the first main light emitting region (33AA) as viewed in the thickness direction (Z direction), and
an area of the second light emitting region (33BB) is smaller than an area of the second main light emitting region (33AB) as viewed in the thickness direction (Z direction).

### Clause B13

The surface emitting laser chip according to Clause B12, in which
each of the first light emitting region (33BA), the second light emitting region (33BB), the first main light emitting region (33AA), and the second main light emitting region (33AB) includes at least one light emitting unit (33P) configured to emit laser light,
the at least one light emitting unit (33P) of the first light emitting region (33BA) is smaller in number than the at least one light emitting unit (33P) of the first main light emitting region (33AA), and
the at least one light emitting unit (33P) of the second light emitting region (33BB) is smaller in number than the at least one light emitting unit (33P) of the second main light emitting region (33AB).

### Clause B14

The surface emitting laser chip according to any one of Clauses B9 to B13, in which
the first light emitting surface (33A) includes a third main light emitting region (33AC) and a fourth main light emitting region (33AD) arranged to be separated from each other,
the second light emitting surface (33B) includes a third light emitting region (33BC) and a fourth light emitting region (33BD) arranged to be separated from each other, and
the electrode (34) includes a third electrode (34C) and a fourth electrode (34D) arranged to be separated from each other.

### Clause B15

The surface emitting laser chip according to Clause B14, in which
each of the third light emitting region (33BC), the fourth light emitting region (33BD), the third main light emitting region (33AC), and the fourth main light emitting region (33AD) includes a light emitting unit (33P) configured to emit laser light,
the third electrode (34C) is electrically connected to both the light emitting unit (33P) of the third light emitting region (33BC) and the light emitting unit (33P) of the third main light emitting region (33AC), and
the fourth electrode (34D) is electrically connected to both the light emitting unit (33P) of the fourth light emitting region (33BD) and the light emitting unit (33P) of the fourth main light emitting region (33AD).

### Clause B16

The surface emitting laser chip according to Clause B14 or B15, in which
an area of the third light emitting region (33BC) is smaller than an area of the third main light emitting region (33AC) as viewed in the thickness direction (Z direction), and
an area of the fourth light emitting region (33BD) is smaller than an area of the fourth main light emitting region (33AD) as viewed in the thickness direction (Z direction).

### Clause B17

The surface emitting laser chip according to Clause B16, in which
each of the third light emitting region (33BC), the fourth light emitting region (33BD), the third main light emitting region (33AC), and the fourth main light emitting region (33AD) includes at least one light emitting unit (33P) configured to emit laser light,
the at least one light emitting unit (33P) of the third light emitting region (33BC) is smaller in number than the at least one light emitting unit (33P) of the third main light emitting region (33AC), and
the at least one light emitting unit (33P) of the fourth light emitting region (33BD) is smaller in number than the at least one light emitting unit (33P) of the fourth main light emitting region (33AD).

### Clause B18

The surface emitting laser chip according to any one of Clauses B14 to B17, in which
a direction orthogonal to the first direction (X direction) as viewed from the thickness direction (Z direction) is defined as a second direction (Y direction),
the first light emitting region (33BA), the second light emitting region (33BB), the third light emitting region (33BC), and the fourth light emitting region (33BD) are arranged to be separated from each other in the second direction (Y direction),
the first main light emitting region (33AA), the second main light emitting region (33AB), the third main light emitting region (33AC), and the fourth main light emitting region (33AD) are arranged to be separated from each other in the second direction (Y direction),
the first electrode (34A), the second electrode (34B), the third electrode (34C), and the fourth electrode (34D) are arranged to be separated from each other in the second direction (Y direction),
the third light emitting region (33BC), the third main light emitting region (33AC), and the third electrode (34C) are provided at the same position in the second direction (Y direction), and
the fourth light emitting region (33BD), the fourth main light emitting region (33AD), and the fourth electrode (34D) are provided at the same position in the second direction (Y direction).

### Clause B19

The surface emitting laser chip according to Clause B18, in which
the third light emitting region (33BC) and the fourth light emitting region (33BD) are provided between the first light emitting region (33BA) and the second light emitting region (33BB) in the second direction (Y direction),
the third main light emitting region (33AC) and the fourth main light emitting region (33AD) are provided between the first main light emitting region (33AA) and the second main light emitting region (33AB) in the second direction (Y direction), and
a length of each of the first main light emitting region (33AA) and the second main light emitting region (33AB) in the first direction (X direction) is smaller than a length of each of the third main light emitting region (33AC) and the fourth main light emitting region (33AD) in the first direction (X direction).

### Clause B20

The surface emitting laser chip according to Clause B18 or B19, in which
each of the third light emitting region (33BC), the fourth light emitting region (33BD), the third main light emitting region (33AC), and the fourth main light emitting region (33AD) includes at least one light emitting unit (33P) configured to emit laser light,
the third light emitting region (33BC) and the fourth light emitting region (33BD) are provided between the first light emitting region (33BA) and the second light emitting region (33BB) in the second direction (Y direction),
the third main light emitting region (33AC) and the fourth main light emitting region (33AD) are provided between the first main light emitting region (33AA) and the second main light emitting region (33AB) in the second direction (Y direction), and
the at least one light emitting unit (33P) of the first main light emitting region (33AA) and the second main light emitting region (33AB) is smaller in number than the at least one light emitting unit (33P) of the third main light emitting region (33AC) and the fourth main light emitting region (33AD).

### Clause B21

The surface emitting laser chip according to Clause B14, in which
a length of the first main light emitting region (33AA) in the first direction (X direction) is equal to a length of the second main light emitting region (33AB) in the first direction (X direction), and
a length of the third main light emitting region (33AC) in the first direction (X direction) is equal to a length of the fourth main light emitting region (33AD) in the first direction (X direction).

### Clause B22

The surface emitting laser chip according to Clause B21, in which centers of the first main light emitting region (33AA), the second main light emitting region (33AB), the third main light emitting region (33AC), and the fourth main light emitting region (33AD) in the first direction (X direction) are located at the same position in the first direction (X direction).

### Clause B23

The surface emitting laser chip according to Clause B22, in which the first light emitting surface (33A) has a circular shape as viewed in the thickness direction (Z direction).

The above description is merely exemplary. Those skilled in the art will recognize that various further combinations and permutations are possible in addition to the components and methods (manufacturing process) that are listed for the purpose of describing the techniques of the present disclosure. The present disclosure is intended to cover all alternatives, variations, and modifications falling within the scope of this disclosure, including the claims and clauses.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light emitting device, comprising:
a surface emitting laser chip having a light emitting surface and configured to emit laser light from the light emitting surface;
a light receiving chip;
a sealing member that is formed of a material through which the laser light can pass and seals the surface emitting laser chip and the light receiving chip; and
a reflecting portion that is provided in the sealing member and reflects a part of the laser light toward the light receiving chip,
wherein the light receiving chip is arranged at a position where the light receiving chip receives at least a part of reflected light by the reflecting portion.

2. The semiconductor light emitting device according to claim 1, wherein the reflecting portion includes irregularities formed on a part of a sealing surface of the sealing member.

3. The semiconductor light emitting device according to claim 2, wherein
the sealing surface of the sealing member includes a flat surface and a rough surface rougher than the flat surface, and
the reflecting portion includes the rough surface.

4. The semiconductor light emitting device according to claim 1, wherein the reflecting portion includes a reflecting layer formed on a sealing surface of the sealing member.

5. The semiconductor light emitting device according to claim 1, wherein
the sealing member includes a sealing surface through which the laser light passes, and a recess formed in a part of the sealing surface, and
the reflecting portion includes a reflecting layer provided in the recess.

6. The semiconductor light emitting device according to claim 1, further comprising a light shielding layer formed in a portion of the sealing surface of the sealing member, the portion overlapping with the light receiving chip as viewed in a direction perpendicular to the sealing surface.

7. The semiconductor light emitting device according to claim 6, wherein the light shielding layer covers the reflecting portion.

8. The semiconductor light emitting device according to claim 1, wherein
the light emitting surface of the surface emitting laser chip and the light receiving surface of the light receiving chip are arranged to be separated from each other in a first direction as viewed in a direction perpendicular to a sealing surface of the sealing member, and
the reflecting portion is formed between the light emitting surface and the light receiving surface in the first direction as viewed from the direction perpendicular to the sealing surface.

9. The semiconductor light emitting device according to claim 8, wherein the reflecting portion is provided so as to extend over the surface emitting laser chip and the light receiving chip in the first direction as viewed from the direction perpendicular to the sealing surface.

10. The semiconductor light emitting device according to claim 1, wherein
a chip front surface of the surface emitting laser chip includes the light emitting surface and an electrode formed to be separated from the light emitting surface in a first direction as viewed from a direction perpendicular to the chip front surface, and
the light receiving chip is arranged on a side opposite to the electrode with respect to the light emitting surface in the first direction.

11. The semiconductor light emitting device according to claim 1, further comprising a substrate, wherein
the surface emitting laser chip is arranged on the substrate, and
the light receiving chip is arranged on the substrate to be separated from the surface emitting laser chip in a first direction as viewed from a thickness direction of the substrate.

12. The semiconductor light emitting device according to claim 11, further comprising a detection light receiving chip that is arranged on the substrate and is configured to receive reflected light that is the laser light emitted from the surface emitting laser chip and reflected by an object,
wherein the detection light receiving chip is arranged on a side opposite to the light receiving chip with respect to the surface emitting laser chip in the first direction.

13. The semiconductor light emitting device according to claim 11, further comprising a submount substrate interposed between the substrate and the surface emitting laser chip in the thickness direction of the substrate.

14. The semiconductor light emitting device according to claim 13, further comprising a detection light receiving chip that is arranged on the substrate and is configured to receive reflected light that is the laser light emitted from the surface emitting laser chip and reflected by an object, wherein
the surface emitting laser chip includes a chip back surface opposite to the light emitting surface in the thickness direction, and
the detection light receiving chip is arranged closer to the substrate than the chip back surface is in the thickness direction.

15. The semiconductor light emitting device according to claim 1, wherein
the light receiving chip includes a light receiving element and a chip front surface,
the chip front surface includes a light receiving surface of the light receiving element, and
the surface emitting laser chip is bonded to the chip front surface of the light receiving chip, and the surface emitting laser chip is arranged at a position different from the light receiving surface of the light receiving element as viewed from a direction perpendicular to the chip front surface.

16. The semiconductor light emitting device according to claim 15, wherein
the light receiving chip further includes a detection light receiving element that is configured to receive reflected light that is the laser light emitted from the surface emitting laser chip and reflected by an object, and
the detection light receiving element is formed on a side opposite to the light receiving element with respect to the surface emitting laser chip in a first direction of the light receiving chip as viewed from a direction perpendicular to the chip front surface.

17. The semiconductor light emitting device according to claim 16, wherein
a direction orthogonal to the first direction as viewed from a direction perpendicular to the chip front surface is defined as a second direction, and
the sealing member includes a slit extending in the second direction and a depth direction perpendicular to the chip front surface and being formed between the surface emitting laser chip and a detection surface of the detection light receiving element in the first direction.

18. The semiconductor light emitting device according to claim 1, wherein the reflecting portion includes multiple diffusing materials that are provided in the sealing member and diffuse the laser light.

19. The semiconductor light emitting device according to claim 1, wherein the light receiving chip includes a photodiode.

20. The semiconductor light emitting device according to claim 1, wherein
the surface emitting laser chip is configured to emit laser light having a specific wavelength different from visible light, and
the sealing member is made of a material that blocks the visible light and transmits the laser light having the specific wavelength.
